(19) United States
(12) Patent Application Publication
(10) Pub. No.: US 2010/0001338 A1
(43) Pub. Date: Jan. 7, 2010

(54) Non-volatile semiconductor memory device, and manufacture method for non-volatile semiconductor memory device

(75) Inventor: Kenichiro Nakagawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/458,151

(22) Filed: Jul. 1, 2009

(30) Foreign Application Priority Data
Jul. 3, 2008 (JP) 2008-174699

(51) Int. Cl. H01L 29/792; H01L 21/336; H01L 21/8246

(52) U.S. Cl. 257/324; 438/589; 438/591; 257/E21.662; 257/E21.423; 257/E29.309

(57) ABSTRACT

A non-volatile semiconductor memory device includes a semiconductor substrate, a charge-storage layer that is formed above the semiconductor substrate, a first gate that is formed above the charge-storage layer, and that includes a first surface and a second surface, a second gate that is formed beside the first surface of the first gate, an insulating layer that is formed above the second surface of the first gate, a diffusion region that is formed on the semiconductor substrate at a position corresponding to the second surface of the first gate, and a silicide layer that is formed above the insulating layer and the diffusion region.

### INCORPORATION BY REFERENCE

This application is based upon and claims the benefit of priority from Japanese Patent Application No. 2008-174699 which was filed on Jul. 3, 2008, the disclosure of which is incorporated herein in its entirety by reference.

### BACKGROUND OF THE INVENTION

1. Field of the Invention

The present invention relates to a non-volatile semiconductor memory device, and to a manufacture method for the non-volatile semiconductor memory device.

2. Description of Related Art

In response to advances in functionality and performance of information processors, non-volatile semiconductor devices with higher integration density are now demanded. To increase the integration density of a non-volatile semiconductor device, storage elements constituting the non-volatile semiconductor memory device are miniaturized by using some known technologies (see JP-A-2006-114921, for example).

JP-A-2006-114921 describes a technique for forming a non-volatile memory device by a self-alignment method. In the case of the technique described in JP-A-2006-114921, an electron-trapping dielectric material is formed on a substrate. Subsequently, a conductive material is formed on the dielectric material, and thereafter, a material spacer is formed on the conductive material. Afterward, segments to be disposed under the material spacer are formed by removing parts of the dielectric material and the conductive material. Thereby, first and second spaced-apart regions of a second conductivity type different from the conductivity type of the substrate are formed in the substrate.

In the technique described in JP-A-2006-1214921, the memory device is formed as follows. A channel region is extended between the first and second regions, and the segments of the dielectric material and a first conductive material are disposed on a first portion of the channel region for controlling the conductivity thereof. In addition, a second conductive material is formed on a second portion of the channel region, and is insulated from the channel region so that the conductivity thereof is controlled.

In response to the advancement of information processing technologies, there has been a high demand for faster operation of non-volatile semiconductor memory devices. In addition, there has been a demand also for a higher integration density of the non-volatile semiconductor memory device. For these reasons, it is demanded that storage elements should be further miniaturized.

### SUMMARY

However, the present inventor has recognized the following point. Namely, the memory device described in JP-A-2006-1214921 is manufactured by use of the self-alignment method. When the memory device is manufactured in a smaller scale, the interstice between each two elements symmetrically disposed becomes narrower, and thus the width of polysilicon (i.e., a source plug) formed on a source diffusion layer becomes smaller as well.

Reduction in the width of the source plug in response to the miniaturization of the storage element increases the resistance of the source plug. When the resistance of the source plug is large, it is likely that the electric current (ON current) for operating the non-semiconductor memory device at a higher speed cannot be achieved sufficiently.

An exemplary problem to be solved by the present invention is to provide a non-volatile semiconductor memory device capable of performing high-speed operation with an increase in the area thereof being suppressed.

The present invention seeks to solve one or more of the above problems, or to improve upon those problems at least in part.

In one exemplary embodiment, a non-volatile semiconductor memory device according to the present invention includes a semiconductor substrate, a charge-storage layer that is formed above the semiconductor substrate, a first gate that is formed above the charge-storage layer, and that includes a first surface and a second surface, a second gate that is formed beside the first surface of the first gate, an insulating layer that is formed above the second surface of the first gate, a diffusion region that is formed on the semiconductor substrate at a position corresponding to the second surface of the first gate, and a silicide layer that is formed above the insulating layer and the diffusion region.

In another exemplary embodiment, a nonvolatile semiconductor device according to the present invention includes a semiconductor substrate, a first gate that is formed above the semiconductor substrate, a second gate that is formed above the semiconductor substrate, a diffusion region that is formed on the semiconductor substrate at a position corresponding to a region between the first gate and the second gate, a first charge-storage layer that is formed above the semiconductor substrate at a position corresponding to a region between the first gate and the diffusion region, a second charge-storage layer that is formed above the semiconductor substrate at a position corresponding to a region between the second gate and the diffusion region, a third gate that is formed above the first charge-storage layer, and that includes a first surface corresponding to a side of the diffusion region, a fourth gate that is formed above the second charge-storage layer, and that includes a second surface corresponding to the side of the diffusion region, a first insulating layer that is formed above the first surface of the third gate, a second insulating layer that is formed above the second surface of the fourth gate, and a silicide layer that is formed above the diffusion region, the first insulating layer, and the second insulating layer.

In yet another exemplary embodiment, a manufacture method for a non-volatile semiconductor memory device according to the present invention includes forming a first gate above a semiconductor substrate, forming a charge-storage layer at a side of the first gate, forming a second gate above the charge-storage layer, forming a diffusion region on the semiconductor substrate at a position corresponding to a side of the second gate, covering the second gate with a sidewall insulating layer, covering the sidewall insulating layer with a sidewall conductive layer, and siliciding the sidewall conductive layer to form a silicide layer.

The present invention is capable of configuring a non-volatile semiconductor memory device capable of performing a high speed operation with an increase in the area thereof being suppressed.

### BRIEF DESCRIPTION OF THE DRAWINGS

The above and other purposes, advantages and features of the present invention will become more apparent from the following description of certain exemplary embodiments taken in conjunction with the accompanying drawings in which:

FIG. 1 is a perspective view illustrating a three-dimensional configuration of a storage element 1 in a semiconductor device 10 according to a first exemplary embodiment;

FIG. 2 is a plan view illustrating a configuration of the semiconductor device 10 according to the first exemplary embodiment;

FIG. 3 is a cross-sectional view illustrating a configuration of a cross-section along A1-A1′ of FIG. 2;

FIG. 4 is a cross-sectional view illustrating a configuration of another cross-section along A2-A2′ of FIG. 2;

FIG. 5 is a cross-sectional view illustrating a configuration of a cross-section along A3-A3′ of FIG. 2;

FIG. 6 is a cross-sectional view illustrating a configuration of another cross-section along A4-A4′ of FIG. 2;

FIG. 7A is a plan view illustrating a first step of a manufacturing for the semiconduct or device 10 according to the first exemplary embodiment;

FIG. 7B is a cross-sectional view illustrating the first step of the manufacturing for a cross-section along B-B′ of FIG. 7A;

FIG. 7C is a cross-sectional view illustrating the first step of the manufacturing for a cross-section along C-C′ of FIG. 7A;

FIG. 7D is a cross-sectional view illustrating the first step of the manufacturing for a cross-section along D-D′ of FIG. 7A;

FIG. 7E is a cross-sectional view illustrating the first step of the manufacturing for a cross-section along E-E′ of FIG. 7A;

FIG. 8A is a plan view illustrating a second step of a manufacturing for the semiconductor device 10 according to the first exemplary embodiment;

FIG. 8B is a cross-sectional view illustrating the second step of the manufacturing for a cross-section along B-B′ of FIG. 8A;

FIG. 8C is a cross-sectional view illustrating the second step of the manufacturing for a cross-section along C-C′ of FIG. 8A;

FIG. 8D is a cross-sectional view illustrating the second step of the manufacturing for a cross-section along D-D′ of FIG. 8A;

FIG. 8E is a cross-sectional view illustrating the second step of the manufacturing for a cross-section along E-E′ of FIG. 8A;

FIG. 9A is a plan view illustrating a third step of a manufacturing for the semiconductor device 10 according to the first exemplary embodiment;

FIG. 9B is a cross-sectional view illustrating the third step of the manufacturing for a cross-section along B-B′ of FIG. 9A;

FIG. 9C is a cross-sectional view illustrating the third step of the manufacturing for a cross-section along C-C′ of FIG. 9A;

FIG. 9D is a cross-sectional view illustrating the third step of the manufacturing for a cross-section along D-D′ of FIG. 9A;

FIG. 9E is a cross-sectional view illustrating the third step of the manufacturing for a cross-section along E-E′ of FIG. 9A;

FIG. 10A is a plan view illustrating a fourth step of a manufacturing for the semiconductor device 10 according to the first exemplary embodiment;

FIG. 10B is a cross-sectional view illustrating the fourth step of the manufacturing for a cross-section along B-B′ of FIG. 10A;

FIG. 10C is a cross-sectional view illustrating the fourth step of the manufacturing for a cross-section along C-C′ of FIG. 10A;

FIG. 10D is a cross-sectional view illustrating the fourth step of the manufacturing for a cross-section along D-D′ of FIG. 10A;

FIG. 10E is a cross-sectional view illustrating the fourth step of the manufacturing for a cross-section along E-E′ of FIG. 10A;

FIG. 11A is a plan view illustrating a fifth step of a manufacturing for the semiconductor device 10 according to the first exemplary embodiment;

FIG. 11B is a cross-sectional view illustrating the fifth step of the manufacturing for a cross-section along B-B′ of FIG. 11A;

FIG. 11C is a cross-sectional view illustrating the fifth step of the manufacturing for a cross-section along C-C′ of FIG. 11A;

FIG. 11D is a cross-sectional view illustrating the fifth step of the manufacturing for a cross-section along D-D′ of FIG. 11A;

FIG. 11E is a cross-sectional view illustrating the fifth step of the manufacturing for a cross-section along E-E′ of FIG. 11A;

FIG. 12A is a plan view illustrating a sixth step of a manufacturing for the semiconductor device 10 according to the first exemplary embodiment;

FIG. 12B is a cross-sectional view illustrating the sixth step of the manufacturing for a cross-section along B-B′ of FIG. 12A;

FIG. 12C is a cross-sectional view illustrating the sixth step of the manufacturing for a cross-section along C-C′ of FIG. 12A;

FIG. 12D is a cross-sectional view illustrating the sixth step of the manufacturing for a cross-section along D-D′ of FIG. 12A;

FIG. 12E is a cross-sectional view illustrating the sixth step of the manufacturing for a cross-section along E-E′ of FIG. 12A;

FIG. 13A is a plan view illustrating a seventh step of a manufacturing for the semiconductor device 10 according to the first exemplary embodiment;

FIG. 13B is a cross-sectional view illustrating the seventh step of the manufacturing for a cross-section along B-B′ of FIG. 13A;

FIG. 13C is a cross-sectional view illustrating the seventh step of the manufacturing for a cross-section along C-C′ of FIG. 13A;

FIG. 13D is a cross-sectional view illustrating the seventh step of the manufacturing for a cross-section along D-D′ of FIG. 13A;

FIG. 13E is a cross-sectional view illustrating the seventh step of the manufacturing for a cross-section along E-E′ of FIG. 13A;

FIG. 14A is a plan view illustrating an eighth step of a manufacturing for the semiconductor device 10 according to the first exemplary embodiment;

FIG. 14B is a cross-sectional view illustrating the eighth step of the manufacturing for a cross-section along B-B′ of FIG. 14A;

FIG. 14C is a cross-sectional view illustrating the eighth step of the manufacturing for a cross-section along C-C′ of FIG. 14A;

FIG. 14D is a cross-sectional view illustrating the eighth step of the manufacturing for a cross-section along D-D′ of FIG. 14A;

FIG. 14E is a cross-sectional view illustrating the eighth step of the manufacturing for a cross-section along E-E′ of FIG. 14A;

FIG. 15A is a plan view illustrating a ninth step of a manufacturing for the semiconductor device 10 according to the first exemplary embodiment;

FIG. 15B is a cross-sectional view illustrating the ninth step of the manufacturing for a cross-section along B-B′ of FIG. 15A;

FIG. 15C is a cross-sectional view illustrating the ninth step of the manufacturing for a cross-section along C-C′ of FIG. 15A;

FIG. 15D is a cross-sectional view illustrating the ninth step of the manufacturing for a cross-section along D-D′ of FIG. 15A;

FIG. 15E is a cross-sectional view illustrating the ninth step of the manufacturing for a cross-section along E-E′ of FIG. 15A;

FIG. 16A is a plan view illustrating a tenth step of a manufacturing for the semiconductor device 10 according to the first exemplary embodiment;

FIG. 16B is a cross-sectional view illustrating the tenth step of the manufacturing for a cross-section along B-B′ of FIG. 16A;

FIG. 16C is a cross-sectional view illustrating the tenth step of the manufacturing for a cross-section along C-C′ of FIG. 16A;

FIG. 16D is a cross-sectional view illustrating the tenth step of the manufacturing for a cross-section along D-D′ of FIG. 16A;

FIG. 16E is a cross-sectional view illustrating the tenth step of the manufacturing for a cross-section along E-E′ of FIG. 16A;

FIG. 17A is a plan view illustrating an eleventh step of a manufacturing for the semiconductor device 10 according to the first exemplary embodiment;

FIG. 17B is a cross-sectional view illustrating the eleventh step of the manufacturing for a cross-section along B-B′ of FIG. 17A;

FIG. 17C is a cross-sectional view illustrating the eleventh step of the manufacturing for a cross-section along C-C′ of FIG. 17A;

FIG. 17D is a cross-sectional view illustrating the eleventh step of the manufacturing for a cross-section along D-D′ of FIG. 17A;

FIG. 17E is a cross-sectional view illustrating the eleventh step of the manufacturing for a cross-section along E-E′ of FIG. 17A;

FIG. 18 is a perspective view illustrating a three-dimensional configuration of a storage element 1 in a semiconductor device 10 according to a second exemplary embodiment;

FIG. 19 is a plan view illustrating a configuration of the semiconductor device 10 according to the second exemplary embodiment;

FIG. 20 is a cross-sectional view illustrating a configuration of a cross-section along A1-A1′ of FIG. 19;

FIG. 21 is across-sectional view illustrating a configuration of another cross-section along A2-A2′ of FIG. 19;

FIG. 22 is a cross-sectional view illustrating a configuration of a cross-section along A3-A3′ of FIG. 19;

FIG. 23 is a cross-sectional view illustrating a configuration of another cross-section along A4-A4′ of FIG. 19;

FIG. 24A is a plan view illustrating a first step of a manufacturing for the semiconductor device 10 according to the second exemplary embodiment;

FIG. 24B is a cross-sectional view illustrating the first step of the manufacturing for a cross-section along B-B′ of FIG. 24A;

FIG. 24C is a cross-sectional view illustrating the first step of the manufacturing for a cross-section along C-C′ of FIG. 24A;

FIG. 24D is a cross-sectional view illustrating the first step of the manufacturing for a cross-section along D-D′ of FIG. 24A;

FIG. 24E is a cross-sectional view illustrating the first step of the manufacturing for a cross-section along E-E′ of FIG. 24A;

FIG. 25A is a plan view illustrating a second step of a manufacturing for the semiconductor device 10 according to the second exemplary embodiment;

FIG. 25B is a cross-sectional view illustrating the second step of the manufacturing for a cross-section along B-B′ of FIG. 25A;

FIG. 25C is a cross-sectional view illustrating the second step of the manufacturing for a cross-section along C-C′ of FIG. 25A;

FIG. 25D is a cross-sectional view illustrating the second step of the manufacturing for a cross-section along D-D′ of FIG. 25A;

FIG. 25E is a cross-sectional view illustrating the second step of the manufacturing for a cross-section along E-E′ of FIG. 25A;

FIG. 26A is a plan view illustrating a third step of a manufacturing for the semiconductor device 10 according to the second exemplary embodiment;

FIG. 26B is a cross-sectional view illustrating the third step of the manufacturing for a cross-section along B-B′ of FIG. 26A;

FIG. 26C is a cross-sectional view illustrating the third step of the manufacturing for a cross-section along C-C′ of FIG. 26A;

FIG. 26D is a cross-sectional view illustrating the third step of the manufacturing for a cross-section along D-D′ of FIG. 26A;

FIG. 26E is a cross-sectional view illustrating the third step of the manufacturing for a cross-section along E-E′ of FIG. 26A;

FIG. 27A is a plan view illustrating a fourth step of a manufacturing for the semiconductor device 10 according to the second exemplary embodiment;

FIG. 27B is a cross-sectional view illustrating the fourth step of the manufacturing for a cross-section along B-B′ of FIG. 27A;

FIG. 27C is a cross-sectional view illustrating the fourth step of the manufacturing for a cross-section along C-C′ of FIG. 27A;

FIG. 27D is a cross-sectional view illustrating the fourth step of the manufacturing for a cross-section along D-D′ of FIG. 27A;

FIG. 27E is a cross-sectional view illustrating the fourth step of the manufacturing for a cross-section along E-E′ of FIG. 27A;

FIG. 28A is a plan view illustrating a fifth step of a manufacturing for the semiconductor device 10 according to the second exemplary embodiment;

FIG. 28B is a cross-sectional view illustrating the fifth step of the manufacturing for a cross-section along B-B′ of FIG. 28A;

FIG. 28C is a cross-sectional view illustrating the fifth step of the manufacturing for a cross-section along C-C′ of FIG. 28A;

FIG. 28D is a cross-sectional view illustrating the fifth step of the manufacturing for a cross-section along D-D′ of FIG. 28A;

FIG. 28E is a cross-sectional view illustrating the fifth step of the manufacturing for a cross-section along E-E′ of FIG. 28A;

FIG. 29A is a plan view illustrating a sixth step of a manufacturing for the semiconductor device 10 according to the second exemplary embodiment;

FIG. 29B is a cross-sectional view illustrating the sixth step of the manufacturing for a cross-section along B-B′ of FIG. 29A;

FIG. 29C is a cross-sectional view illustrating the sixth step of the manufacturing for a cross-section along C-C′ of FIG. 29A;

FIG. 29D is a cross-sectional view illustrating the sixth step of the manufacturing for a cross-section along D-D′ of FIG. 29A;

FIG. 29E is a cross-sectional view illustrating the sixth step of the manufacturing for a cross-section along E-E′ of FIG. 29A;

FIG. 30A is a plan view illustrating a seventh step of a manufacturing for the semiconductor device 10 according to the second exemplary embodiment;

FIG. 30B is a cross-sectional view illustrating the seventh step of the manufacturing for a cross-section along B-B′ of FIG. 30A;

FIG. 30C is a cross-sectional view illustrating the seventh step of the manufacturing for a cross-section along C-C′ of FIG. 30A;

FIG. 30D is a cross-sectional view illustrating the seventh step of the manufacturing for a cross-section along D-D′ of FIG. 30A;

FIG. 30E is a cross-sectional view illustrating the seventh step of the manufacturing for a cross-section along E-E′ of FIG. 30A;

FIG. 31A is a plan view illustrating an eighth step of a manufacturing for the semiconductor device 10 according to the second exemplary embodiment;

FIG. 31B is a cross-sectional view illustrating the eighth step of the manufacturing for a cross-section along B-B′ of FIG. 31A;

FIG. 31C is a cross-sectional view illustrating the eighth step of the manufacturing for a cross-section along C-C′ of FIG. 31A;

FIG. 31D is a cross-sectional view illustrating the eighth step of the manufacturing for a cross-section along D-D′ of FIG. 31A;

FIG. 31E is a cross-sectional view illustrating the eighth step of the manufacturing for a cross-section along E-E′ of FIG. 31A;

FIG. 32A is a plan view illustrating a ninth step of a manufacturing for the semiconductor device 10 according to the second exemplary embodiment;

FIG. 32B is a cross-sectional view illustrating the ninth step of the manufacturing for a cross-section along B-B′ of FIG. 32A;

FIG. 32C is a cross-sectional view illustrating the ninth step of the manufacturing for a cross-section along C-C′ of FIG. 32A;

FIG. 32D is a cross-sectional view illustrating the ninth step of the manufacturing for a cross-section along D-D′ of FIG. 32A;

FIG. 32E is a cross-sectional view illustrating the ninth step of the manufacturing for a cross-section along E-E′ of FIG. 32A;

FIG. 33A is a plan view illustrating a tenth step of a manufacturing for the semiconductor device 10 according to the second exemplary embodiment;

FIG. 33B is a cross-sectional view illustrating the tenth step of the manufacturing for a cross-section along B-B′ of FIG. 33A;

FIG. 33C is a cross-sectional view illustrating the tenth step of the manufacturing for a cross-section along C-C′ of FIG. 33A;

FIG. 33D is a cross-sectional view illustrating the tenth step of the manufacturing for a cross-section along D-D′ of FIG. 33A;

FIG. 33E is a cross-sectional view illustrating the tenth step of the manufacturing for a cross-section along E-E′ of FIG. 33A;

FIG. 34A is a plan view illustrating an eleventh step of a manufacturing for the semiconductor device 10 according to the second exemplary embodiment;

FIG. 34B is a cross-sectional view illustrating the eleventh step of the manufacturing for a cross-section along B-B′ of FIG. 34A;

FIG. 34C is a cross-sectional view illustrating the eleventh step of the manufacturing for a cross-section along C-C′ of FIG. 34A;

FIG. 34D is a cross-sectional view illustrating the eleventh step of the manufacturing for a cross-section along D-D′ of FIG. 34A;

FIG. 34E is a cross-sectional view illustrating the eleventh step of the manufacturing for a cross-section along E-E′ of FIG. 34A;

FIG. 35A is a plan view illustrating a twelfth step of a manufacturing for the semiconductor device 10 according to the second exemplary embodiment;

FIG. 35B is a cross-sectional view illustrating the twelfth step of the manufacturing for a cross-section along B-B′ of FIG. 35A;

FIG. 35C is a cross-sectional view illustrating the twelfth step of the manufacturing for a cross-section along C-C′ of FIG. 35A;

FIG. 35D is a cross-sectional view illustrating the twelfth step of the manufacturing for a cross-section along D-D′ of FIG. 35A;

FIG. 35E is a cross-sectional view illustrating the twelfth step of the manufacturing for a cross-section along E-E′ of FIG. 35A;

FIG. 36A is a plan view illustrating a thirteenth step of a manufacturing for the semiconductor device 10 according to the second exemplary embodiment;

FIG. 36B is a cross-sectional view illustrating the thirteenth step of the manufacturing for a cross-section along B-B′ of FIG. 36A;

FIG. 36C is a cross-sectional view illustrating the thirteenth step of the manufacturing for a cross-section along C-C′ of FIG. 36A;

FIG. 36D is a cross-sectional view illustrating the thirteenth step of the manufacturing for a cross-section along D-D′ of FIG. 36A; and

FIG. 36E is a cross-sectional view illustrating the thirteenth step of the manufacturing for a cross-section along E-E′ of FIG. 36A.

### DETAILED DESCRIPTION OF THE EXEMPLARY EMBODIMENTS

The invention will now be described herein with reference to illustrative exemplary embodiments. Those skilled in the art will recognize that many alternative embodiments can be accomplished using the knowledge of the present invention, and that the invention is not limited to the exemplary embodiments illustrated for explanatory purposes.

### First Exemplary Embodiment

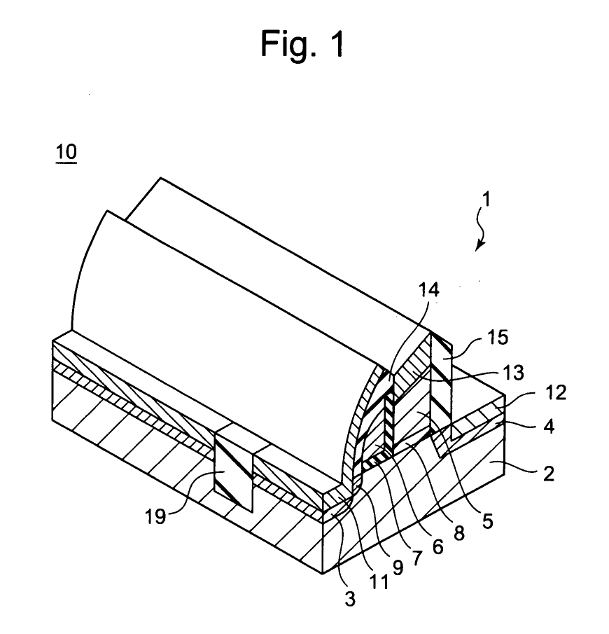

FIG. 1 is a perspective view illustrating a three-dimensional configuration of a storage element 1 included in a semiconductor device 10 of a first exemplary embodiment. The semiconductor device 10 includes multiple storage elements 1. Each of the multiple storage elements 1 includes a first source/drain diffusion layer 3 and a second source/drain diffusion layer 4. The first source/drain diffusion layer 3 and the second source/drain diffusion layer 4 are formed in a semiconductor substrate 2. The storage element 1 includes a control gate 5 and a memory gate 6 which are adjacent to each other with a charge-storage layer (ONO layer) 7 interposed in between. A lightly-doped drain (LDD) region 9 is provided in the semiconductor substrate 2 between the first source/drain diffusion layer 3 and the memory gate 6.

A gate insulating layer 8 is provided between the control gate 5 and the semiconductor substrate 2. The charge-storage layer (ONO layer) 7 is provided between the memory gate 6 and the semiconductor substrate 2. The charge-storage layer 7 is provided between the memory gate 6 and the control gate 5 as well. A sidewall 15 is provided on a side surface of the control gate 5 at a side closer to the second source/drain diffusion layer 4. In addition, a control gate silicide 13 is provided on the control gate 5. A second diffusion layer-side silicide 12 is provided on the second source/drain diffusion layer 4.

A cell sidewall 14 is provided along the side surface of the memory gate 6 up to the top surface thereof, the side surface being located closer to the first source/drain diffusion layer 3. In addition, a first diffusion layer-side silicide 11 is provided along the cell sidewall 14 in such a way as to cover the top and side surfaces of the memory gate 6.

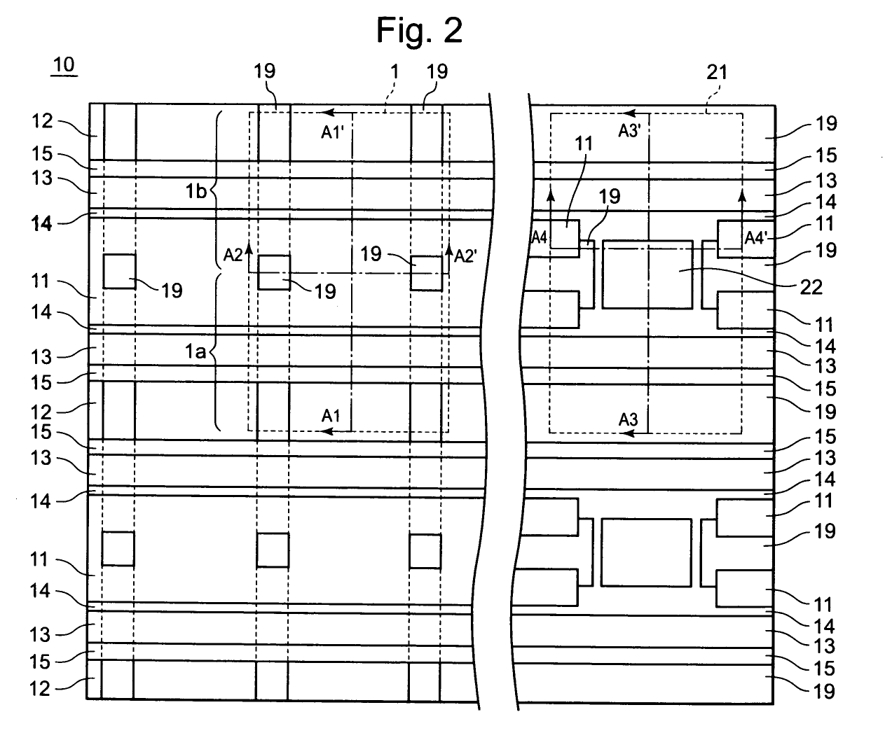

FIG. 2 is a plan view illustrating a configuration of the semiconductor device 10 of the first exemplary embodiment which is viewed from above. Interconnections and via contacts are omitted from the plan view of FIG. 2 so as to facilitate understanding of the present invention. With reference to FIG. 2, each of the multiple storage elements 1 included in the semiconductor 10 includes two memory cells (a first memory cell 1a and a second memory cell 1b). The first memory cell 1a and the second memory cell 1b have the same configuration, and are symmetrical with each other. With this taken into consideration, duplicate descriptions will be hereinafter omitted with regard to the first memory cell 1a and the second memory cell 1b. Furthermore, in the following descriptions of the first exemplary embodiment, one of the two memory cells may be specified. In this case, this specified memory cell corresponds to the first memory cell 1a, and configurations and operations thereof will be described.

The semiconductor device 10 includes: storage element areas, whose storage elements 1 are arranged in an array; and contact areas 21, in each of which a contact (not illustrated) connected to the memory gate 6 is formed. Each storage element area includes: the first source/drain contact 16 (not illustrated) connected to the first diffusion layer-side silicide 11; and the second source/drain contacts 17 (not illustrated) connected to the respective diffusion layer-side silicides 12. As shown in FIG. 2, the multiple storage elements 1 arranged in the semiconductor device 10 are separated from one another by the corresponding element isolation regions 19 each extending in a first direction. The gates (the control gate 5 and the memory gate 6) of each of the multiple storage elements 1 are provided along a second direction orthogonal to the first direction. In addition, each contact area 21 is provided in such a way as to include the element isolation region 19. As shown in FIG. 2, each contact area 21 includes a memory gate silicide 22. The memory gate silicide 22 is configured above the element isolation region 19. A memory gate contact 23 (not illustrated) to be described later is connected to the memory gate silicide 22.

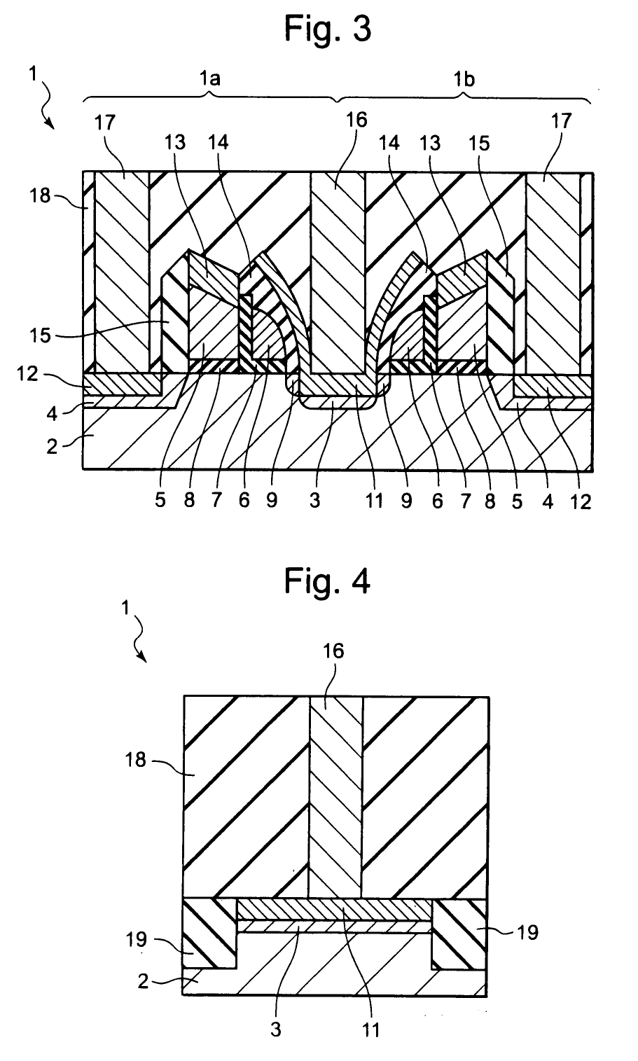

FIG. 3 is a cross-sectional view illustrating a configuration of a cross-section of the storage element 1 of the first exemplary embodiment. FIG. 3 illustrates a cross-sectional configuration of the semiconductor device 10, which is taken along the line A1-A1′ of FIG. 2. As shown in FIG. 3, the sidewall 15 is provided on the side surface of each control gate 5, the side surface being located closer to the corresponding second source/drain diffusion layer 4. The second diffusion layer-side silicides 12 are provided on the second source/drain diffusion layers 4 located at outer sides of the sidewalls 15, respectively. The second source/drain diffusion layers 4 are connected to the second source/drain contacts 17 with the second diffusion layer-side silicides 12 interposed therebetween, respectively. The first source/drain diffusion layer 3 of the first memory cell 1a (or of the second memory cell 1b) is connected to a first source/drain contact 16 with the first diffusion layer-side silicide 11 interposed in between. In the case of the first exemplary embodiment, as shown in FIG. 3, the first source/drain contact 16 is connected to the first diffusion layer-side silicide 11, which is connected to the first source/drain diffusion layer 3 with no polysilicon interposed in between.

FIG. 4 is a cross-sectional view illustrating a configuration of another cross-section of the storage element 1 of the first exemplary embodiment. FIG. 4 illustrates a cross-sectional configuration of the semiconductor device 10 of the first exemplary embodiment, which is taken along the line A2-A2′ of FIG. 2. As shown in FIG. 4, the first source/drain diffusion layer 3 is provided in the semiconductor substrate 2 between the adjacent element isolation regions 19. Similarly to the source/drain diffusion layer 3, the first diffusion layer-side silicide 11 is provided between the element isolation regions 19. The first source/drain contact 16 is provided in a contact hole penetrating an interlayer insulating film 18.

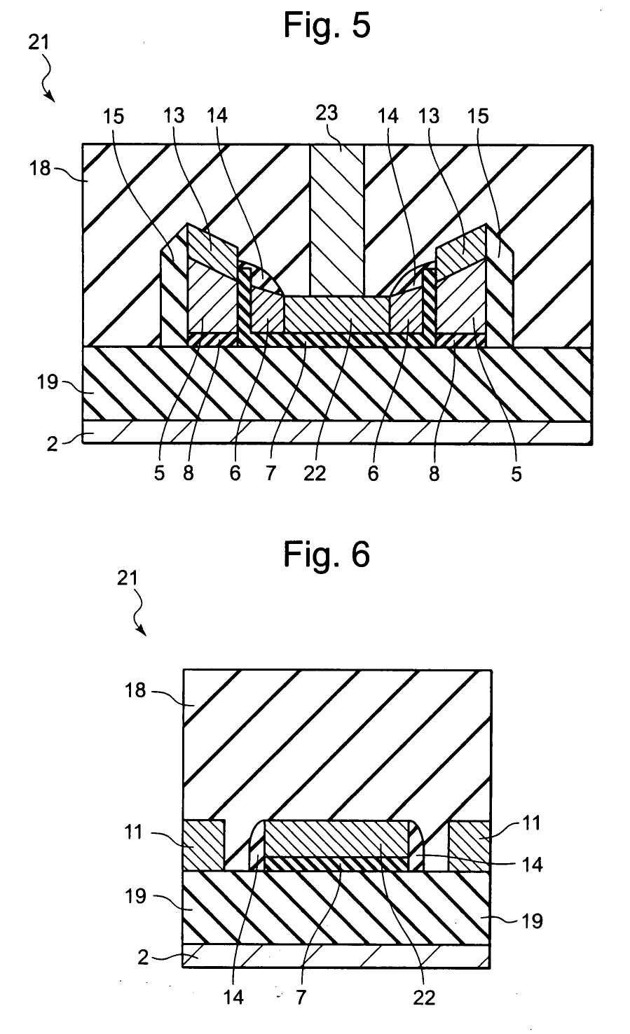

FIG. 5 is a cross-sectional view illustrating a configuration of a cross-section of the contact area 21. FIG. 5 illustrates a configuration of the contact area 21 of the first exemplary embodiment, which is taken along the line A3-A3′ of FIG. 2. The contact area 21 has a symmetrical configuration as in the case of the storage element described above. The contact area 21 is provided on the element isolation region 19 formed on the semiconductor substrate 2. The memory gate silicide 22 of the contact area 21 is connected to the two memory gates 6 facing each other. One of the two memory gates 6 is connected to the memory gate 6 of the first memory cell 1a. The other of the two memory gates 6 is connected to the memory gate 6 of the second memory cell 1b.

The top surfaces of the memory gates 6 included in the contact area 21 are covered with the cell sidewalls 14, respectively. The charge-storage layer (ONO film) 7 is configured between each memory gate 6 and the element isolation region 19. The charge-storage layer (ONO film) 7 is provided between the memory gate silicide 22 and the element isolation region 19 as well. The memory gate contact 23 connected to the memory gate silicide 22 is provided in a contact hole penetrating the interlayer insulating film 18.

FIG. 6 is a cross-sectional view illustrating a configuration of another cross-section of the contact area 21. FIG. 6 illustrates a configuration of the contact area 21 of the first exemplary embodiment, which is taken along the line A4-A4′ of FIG. 2. As shown in FIG. 6, the cell sidewalls 14 are provided on the side surfaces of the memory gate silicide 22 of the contact area 21, respectively. In addition, the memory gate silicide 22 is provided between the adjacent first diffusion layer-side silicides 11.

When information is written into the storage element 1 of the first exemplary embodiment, a positive voltage (for example, 4.5V) is applied to the first source/drain diffusion layer 3. In addition, another positive voltage (for example, 5.5V) is applied to the memory gate 6. Furthermore, yet another positive voltage which is lower than the positive voltage applied to the memory gate 6 is applied to the control gate 5. Moreover, a ground voltage is applied to the second source/drain diffusion layer 4. At this time, parts of electrons flowing from the second source/drain diffusion layer 4 to the first source/drain diffusion layer 3 are accelerated in a channel located under the memory gate 6. The accelerated electrons are injected into the charge-storage layer (ONO film) 7 located immediately under the memory gate 6. Thereby, the information is written.

In the case of erasing the information, a positive voltage (for example, 4.5V) is applied to the first source/drain diffusion layer 3. In addition, a negative voltage (for example, −3.0V) is applied to the memory gate 6. At this time, electron-hole pairs are caused due to an inter-band tunneling formed in a position under the memory gate 6, the position being in a vicinity of the first source/drain diffusion layer 3. Parts of holes in the electron-hole pairs are accelerated by an electric field produced by the first source/drain diffusion layer 3, and are thus injected into the charge-storage layer (ONO film) 7. Thereby, the information is erased. It is desirable that a voltage applied to the control gate 5 should be 0V to −3V when the information is erased.

In the case of reading the information, a ground voltage is applied to the first source/drain diffusion layer 3. In addition, a positive voltage (for example, 2.0V) is applied to the memory gate 6. Furthermore, another positive voltage (for example, 2.0V) is applied to the control gate 5. Moreover, yet another positive voltage (for example, 1.0V) is applied to the second source/drain diffusion layer 4. Subsequently, a current flowing between the second source/drain diffusion layer 4 and the first source/drain diffusion layer 3 is detected. In this event, while electrons are trapped in the charge-storage layer (ONO film) 7 (written state), the amount of current flowing in between is small. On the other hand, while holes are trapped in the charge-storage layer (ONO film) 7, or while almost no charges are trapped in the charge-storage layer (ONO film) 7 (erased state), the amount of current flowing in between is large.

In order to read information from the storage element 1 at high speed, it is desirable that the difference (or the ratio) between the current flowing in the written state and the current flowing in the erased state should be large. With the storage element 1 of the first exemplary embodiment, it is possible to increase the amount of the current flowing in the erased state (ON current). Consequently, the first exemplary embodiment can configure the memory cells capable of performing high speed operations with their areas decreased.

In the first exemplary embodiment, as described above, the first source/drain contact 16 is connected to the first diffusion layer-side silicide 11, which is connected to the first source/drain diffusion layer 3 with no polysilicon interposed in between. This makes it possible to suppress an increase in the resistance between the first source/drain contact 16 and the first source/drain diffusion layer 3 in response to the miniaturization of the memory cells. In addition, the first diffusion layer-side silicide 11 covers the top and side surfaces of each memory gate 6 along the corresponding cell sidewall 14. This makes it possible to prevent the occurrence of failure such as a short circuit between each memory gate 6 and the first source/drain diffusion layer 3 even in a case where the position of the contact hole in which to form the first source/drain contact 16 deviates from its designed position in making the contact hole.

Descriptions will be hereinbelow provided for a manufacturing process for manufacturing the semiconductor device 10 of the first exemplary embodiment. The semiconductor device 10 of the first exemplary embodiment includes: the storage element areas, whose storage elements 1 are arranged in an array; and the contact areas 21. The storage element areas and their respective contact areas 21 are formed simultaneously. The storage element 1 included in each storage element area is arranged in a position away from its corresponding contact area 21. Hereinbelow, descriptions will be provided for the process for manufacturing the semiconductor device 10 by referring to the drawings each omitting the interstice between the contact area 21 and the storage element area provided with the storage element 1.

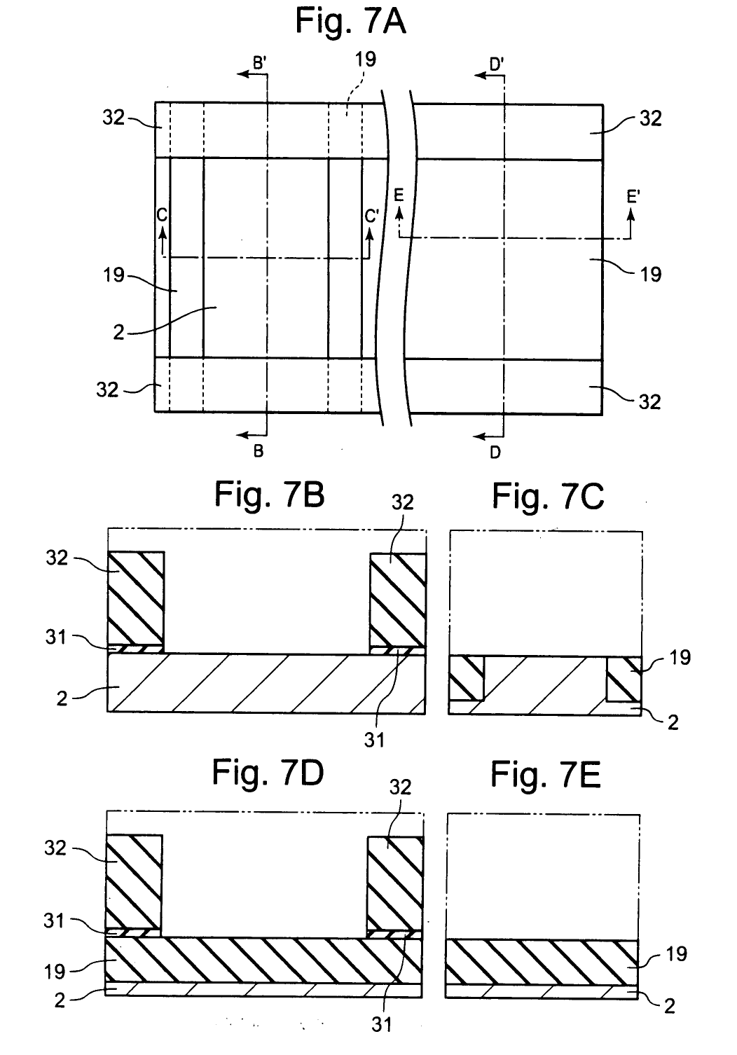

FIGS. 7A to 7E are diagrams illustrating a condition of a first step of manufacturing the semiconductor device 10 of the first exemplary embodiment. FIG. 7A is a plan view of semiconductor materials used in the first step, which are viewed from above. FIG. 7B is a cross-sectional view illustrating a cross-section (hereinafter described as a “B-B′ cross-section”) of the semiconductor materials, which is taken along the line B-B′ of FIG. 7A. FIG. 7C is a cross-sectional view illustrating a cross-section (hereinafter described as a “C-C′ cross-section”) of the semiconductor materials, which is taken along the line C-C′ of FIG. 7A. FIG. 7D is a cross-sectional view illustrating a cross-section (hereinafter described as a “D-D′ cross-section”) of the semiconductor materials, which is taken along the line D-D′ of FIG. 7A. FIG. 7E is a cross-sectional view illustrating a cross-section (hereinafter described as an “E-E′ cross-section”) of the semiconductor materials, which is taken along the line E-E′ of FIG. 7A.

In the first step, as shown in FIGS. 7A to 7E, the element isolation regions 19 are formed in the semiconductor substrate 2. Subsequently, an oxide film 31 and a nitride film 32 are sequentially formed in such a way as to cover the element isolation regions 19 and the semiconductor substrate 2. Thereafter, a resist having a predetermined pattern is formed on the nitride film 32. Afterward, portions respectively of the nitride film 32 and the oxide film 31 are removed by using the resist as a mask.

In the first step, as shown in FIG. 7B, in the storage element area, an opening portion is made between remaining portions of the nitride film 32, and a surface of the semiconductor substrate 2 which corresponds to the opening portion is exposed to the outside. Furthermore, in the first step, as shown in FIG. 7C, in the storage element area, a surface of the semiconductor substrate 2 between the element isolation regions 19 is exposed to the outside. At this time, in the contact area, the element isolation region 19 is formed in the semiconductor substrate 2. In the contact area, as shown in FIGS. 7D and 7E, the element isolation region 19 is exposed through an opening portion between remaining portions of the nitride film 32.

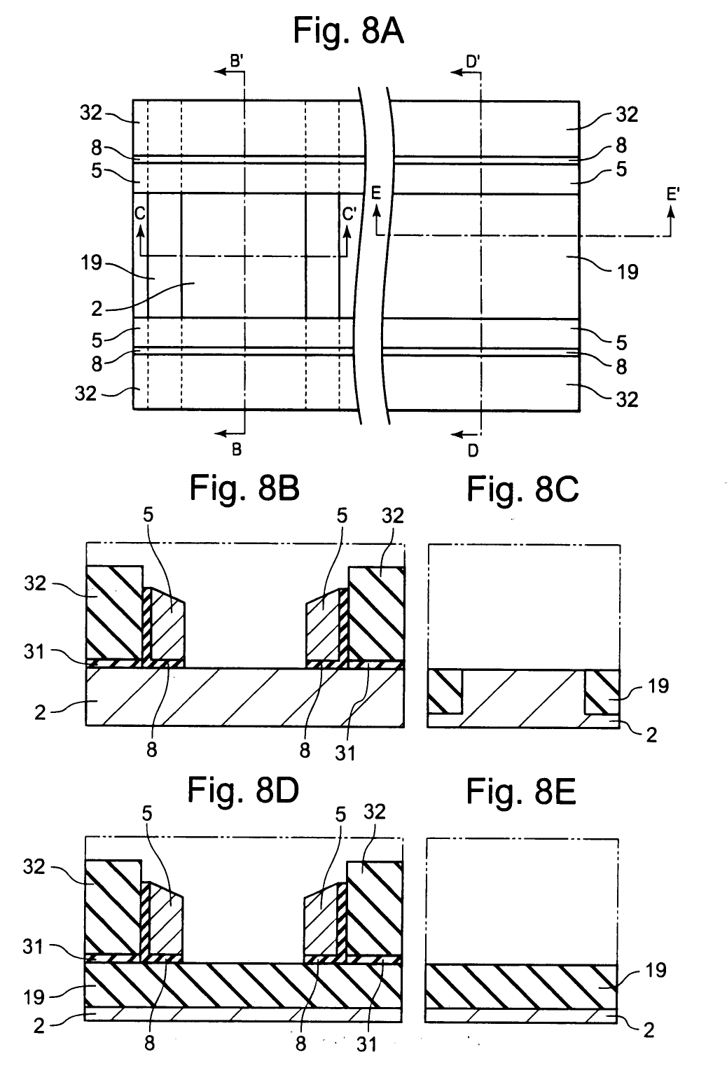

FIGS. 8A to 8E are diagrams illustrating a condition of a second step of manufacturing the semiconductor device 10 of the first exemplary embodiment. FIG. 8A is a plan view of semiconductor materials used in the second step, which are viewed from above. FIG. 8B is a cross-sectional view illustrating a configuration of the B-B′ cross-section. FIG. 8C is a cross-sectional view illustrating a configuration of the C-C′ cross-section. FIG. 8D is a cross-sectional view illustrating a configuration of the D-D′ cross-section. FIG. 8E is a cross-sectional view illustrating a configuration of the E-E′ cross-section.

In the second step, as shown in FIGS. 8A to 8E, an oxide film which will serve as the gate insulating films 8 is formed on the resultant semiconductor substrate 2. Subsequently, polysilicon which will serve as the control gates 5 is formed on the oxide film. Thereafter, the polysilicon is etched back, and the control gates 5 each formed in a sidewall shape are thus formed. Afterward, an unnecessary portion of the oxide film is removed, and the gate insulating films 8 are thus formed.

In the second step, as shown in FIGS. 8B and 8C, the control gates 5 and the gate insulating films 8 are formed in the storage element area. The semiconductor substrate 2 between the control gates 5 facing each other is exposed to the outside. Furthermore, in the second step, as shown in FIGS. 8D and 8E, in the contact area, the control gates 5 and the gate insulating films 8 are formed, and the element isolation region 19 between the control gates 5 facing each other is exposed to the outside.

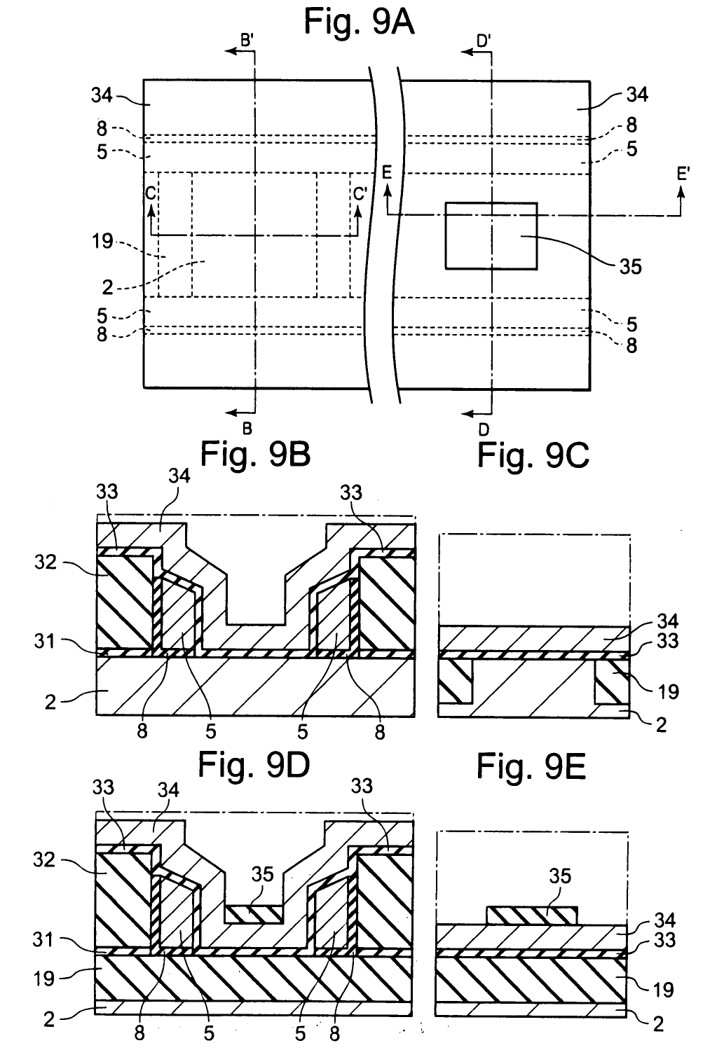

FIGS. 9A to 9E are diagrams illustrating a condition of a third step of manufacturing the semiconductor device 10 of the first exemplary embodiment. FIG. 9A is a plan view of semiconductor materials used in the third step, which are viewed from above. FIG. 9B is a cross-sectional view illustrating a configuration of the B-B′ cross-section. FIG. 9C is a cross-sectional view illustrating a configuration of the C-C′ cross-section. FIG. 9D is a cross-sectional view illustrating a configuration of the D-D′ cross-section. FIG. 9E is a cross-sectional view illustrating a configuration of the E-E′ cross-section.

In the third step, as shown in FIGS. 9A to 9E, a charge-storage film (ONO film) 33 which will serve as the charge-storage layers (ONO layers) 7 is formed. Thereafter, a memory gate polysilicon film 34 which will serve as the memory gates 6 is formed on the charge-storage film (ONO film) 33. In the third step, as shown in FIG. 9A, in the contact area, a first protective oxide film 35 is further formed on the memory gate polysilicon film 34.

In the B-B′ cross-section of the storage element area, as shown in FIG. 9B, the charge-storage film (ONO film) 33 is formed so as to cover the exposed surface of the semiconductor substrate 2, the exposed side and top surfaces of each control gate 5, and the exposed side and top surfaces of each nitride film 32. Subsequently, the memory gate polysilicon film 34 is formed on the charge-storage film (ONO film) 33. In the C-C′ cross-section, as shown in FIG. 9c, the charge-storage film (ONO film) 33 and the memory gate polysilicon film 34 are formed on the element isolation regions 19 as well.

In the D-D′ cross-section of the contact area, as shown in FIG. 9D, the charge-storage film (ONO film) 33 is formed so as to cover the exposed surface of the element isolation region 19, the exposed side and top surfaces of each control gate 5, and the exposed side and top surfaces of each nitride film 32. Subsequently, the memory gate polysilicon film 34 is formed on the charge-storage film (ONO film) 33. The memory gate polysilicon film 34 is formed in such a way as to include an opening portion. The first protective oxide film 35 is formed in such a way as to cover the bottom surface of the opening portion. As shown in FIG. 9E, the first protective oxide film 35 is formed on a position corresponding to a position in which the memory gate silicide 22 is made in the ensuing step.

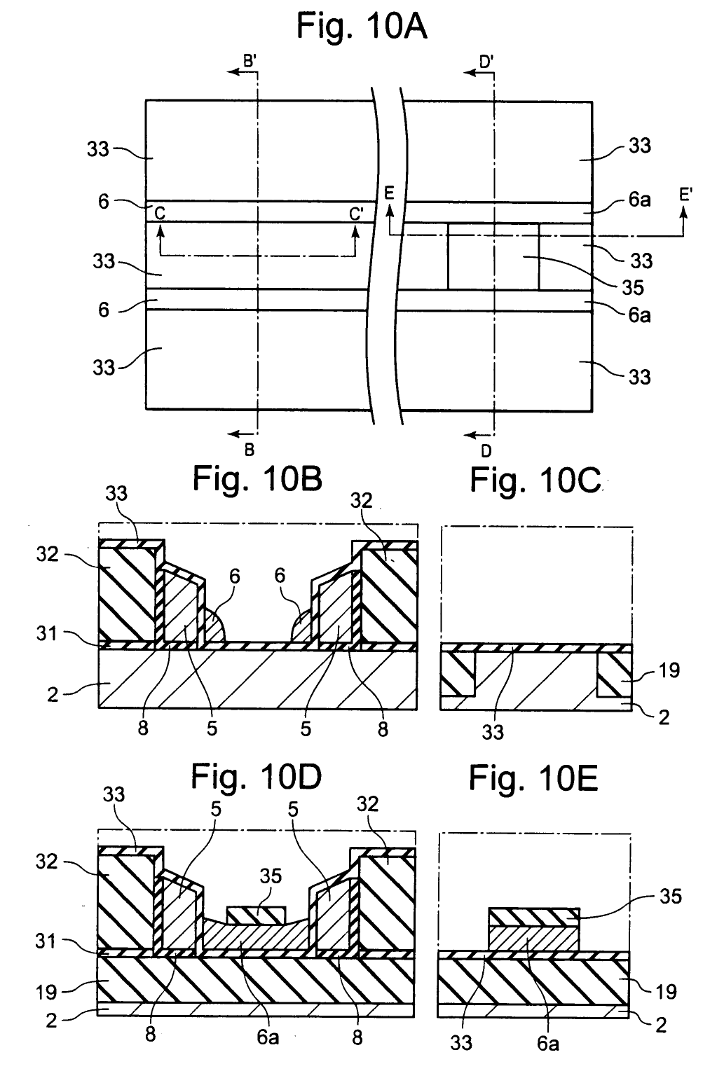

FIGS. 10A to 10E are diagrams illustrating a condition of a fourth step of manufacturing the semiconductor device 10 of the first exemplary embodiment. FIG. 1A is a plan view of semiconductor materials used in the fourth step, which are viewed from above. FIG. 10B is a cross-sectional view illustrating a configuration of the B-B′ cross-section. FIG. 10C is a cross-sectional view illustrating a configuration of the C-C′ cross-section. FIG. 10D is a cross-sectional view illustrating a configuration of the D-D′ cross-section. FIG. 10E is a cross-sectional view illustrating a configuration of the E-E′ cross-section.

In the fourth step, as shown in FIGS. 10A to 10E, the memory gate polysilicon film 34 is etched back, and the memory gates 6 are thus formed. In the B-B′ cross-section of the storage element area, as shown in FIG. 10B, the charge-storage film (ONO film) 33 between the memory gates 6 facing each other is exposed to the outside, after the memory gates 6 are formed. In the C-C′ cross-section, as shown in FIG. 10C, the charge-storage film (ONO film) 33 remains, thereby covering the surfaces of the element isolation regions 19 and the semiconductor substrate 2.

In the D-D′ cross-section of the contact area, as shown in FIG. 10D, a residual portion of the memory gate polysilicon film 34 remains on a side of each control gate 5 and under the first protective oxide film 35. Thus, this residual portion constitutes a memory gate contact region 6a. In the E-E′ cross-section, as shown in FIG. 10E, the memory gate contact region 6a is made under the first protective oxide film 35.

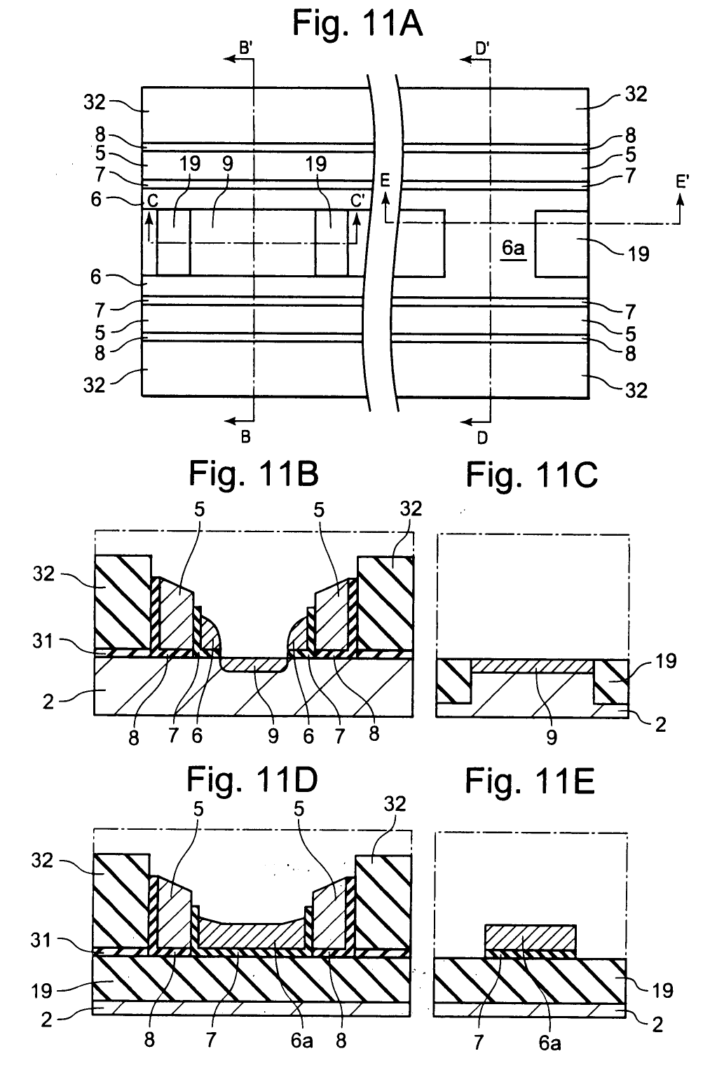

FIGS. 11A to 11E are diagrams illustrating a condition of a fifth step of manufacturing the semiconductor device 10 of the first exemplary embodiment. FIG. 11A is a plan view of semiconductor materials used in the fifth step, which are viewed from above. FIG. 11B is a cross-sectional view illustrating a configuration of the B-B′ cross-section. FIG. 11C is a cross-sectional view illustrating a configuration of the C-C′ cross-section. FIG. 11D is a cross-sectional view illustrating a configuration of the D-D′ cross-section. FIG. 11E is a cross-sectional view illustrating a configuration of the E-E′ cross-section.

In the fifth step, as shown in FIGS. 11A to 11E, a portion of the charge-storage film (ONO film) 33 provided between the memory gates 6 facing each other is removed. Thereby, the charge-storage layers 7 are formed under the respective memory gates 6. Subsequently, impurities (for example, As with a concentration of approximately 1E14/cm²) are implanted into the exposed portion of the semiconductor substrate 2. Thereby, a diffusion layer which will serve as the LDD region 9 is formed. At this time, in the contact area, the first protective oxide film 35 made on the memory gate contact region 6a is removed.

In the fifth step, as shown in FIG. 11B, in the B-B′ cross-section, the charge-storage film (ONO film) 33 covering the control gates 5 and the nitride films 32 is removed. At this time, a portion of the charge-storage film (ONO film) 33 remains between each control gate 5 and its corresponding memory gate 6, and thus electrically insulates the control gate 5 and the memory gate 6. In the C-C′ cross-section, as shown in FIG. 11C, the LDD region 9 is formed between the element isolation regions 19. In the D-D′ cross-section, as shown in FIG. 11D, the first protective oxide film 35 is removed, and the surface of the memory gate contact region 6a is thus exposed to the outside. In addition, a portion of the charge-storage film (ONO film) 33 which covers the control gates 5 and the nitride films 32 is removed with another portion of the charge-storage film (ONO film) 33 remaining underlying the memory gate contact region 6a. Thereby, the charge-storage layer 7 is formed. In the E-E′ cross-section, as shown in FIG. 11E, the first protective oxide film 35 and portions of the charge-storage film (ONO film) 33 are removed. Thereby, surfaces of the element isolation region 19 are exposed to the outside.

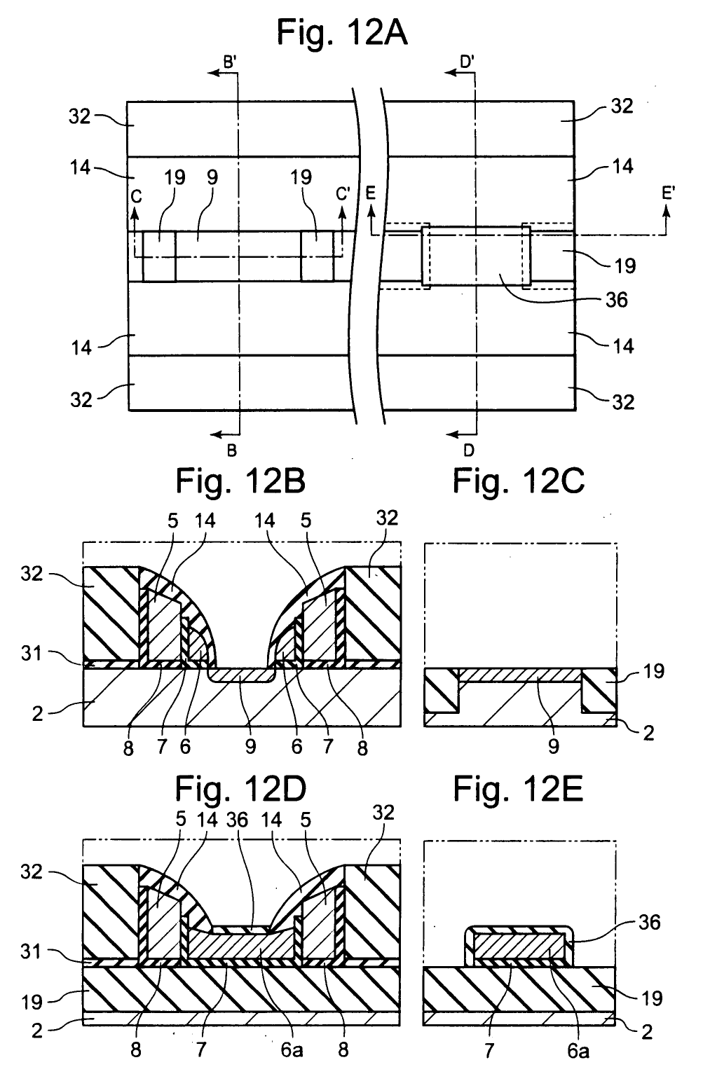

FIGS. 12A to 12E are diagrams illustrating a condition of a sixth step of manufacturing the semiconductor device 10 of the first exemplary embodiment. FIG. 12A is a plan view of semiconductor materials used in the sixth step, which are viewed from above. FIG. 12B is a cross-sectional view illustrating a configuration of the B-B′ cross-section. FIG. 12C is a cross-sectional view illustrating a configuration of the C-C′ cross-section. FIG. 12D is a cross-sectional view illustrating a configuration of the D-D′ cross-section. FIG. 12E is a cross-sectional view illustrating a configuration of the E-E′ cross-section.

In the sixth step, as shown in FIGS. 12A to 12E, an oxide film is formed so as to cover the semiconductor materials entirely. Thereafter, the cell sidewalls 14 are formed by etching back the oxide film. At this time, in the contact area, a second protective oxide film 36 is formed so as to cover the memory gate contact region 6a.

In the sixth step, as shown in FIG. 12B, in the B-B′ cross-section, the side and top surfaces of each memory gate 6 and the top surface of each control gate 5 are covered with a corresponding one of the cell sidewalls 14. In the B-B′ cross-section, the cell sidewalls 14 are configured in such a way as to face each other. As shown in FIG. 12C, the C-C′ cross-section corresponds to the opening portion between the cell sidewalls 14 facing each other, in which the LDD region 9 between the element isolation regions 19 is exposed to the outside.

In the sixth step, as shown in FIG. 12D, in the D-D′ cross-section, portions of the memory gate contact region 6a and the top surfaces of the control gates 5 are covered with the cell sidewalls 14, respectively. The cell sidewalls 14 have an opening portion therebetween, and are configured in such a way as to face each other. In the contact area, the second protective oxide film 36 is formed in the opening portion between the cell sidewall 14 facing each other. As shown in FIG. 12E, the second protective oxide film 36 covers the top and side surfaces of the memory gate contact region 6a. In addition, the second protective oxide film 36 covers the side surfaces of the charge-storage layer 7.

Here, in the sixth step, the cell sidewall 14 is formed, and then the second protective oxide film 36 is newly formed. The sixth step of the first exemplary embodiment, however, is not limited to the above-described manufacturing step, as long as an oxide film for protecting the memory gate contact region 6a is formed. For example, when the cell sidewalls 14 are formed, an oxide film having the same function as the second protective oxide film 36 may be caused to remain on the memory gate contact region 6a instead of being removed therefrom.

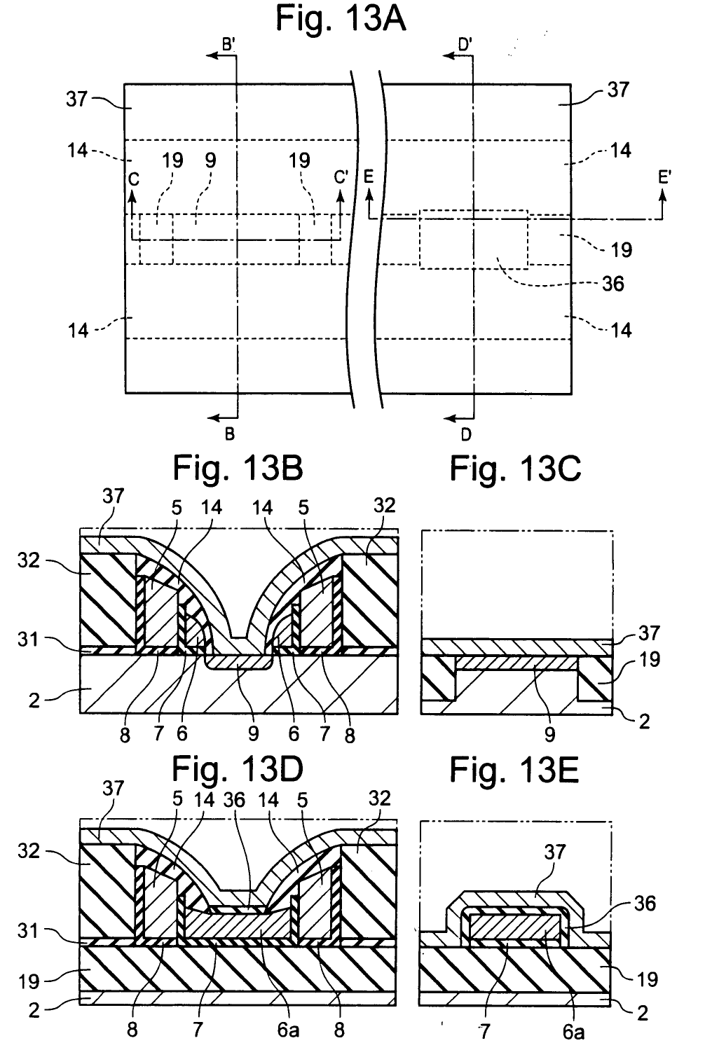

FIGS. 13A to 13E are diagrams illustrating a condition of a seventh step of manufacturing the semiconductor device 10 of the first exemplary embodiment. FIG. 13A is a plan view of semiconductor materials used in the seventh step, which are viewed from above. FIG. 13B is a cross-sectional view illustrating a configuration of the B-B′ cross-section. FIG. 13C is a cross-sectional view illustrating a configuration of the C-C′ cross-section. FIG. 13D is a cross-sectional view illustrating a configuration of the D-D′ cross-section. FIG. 13E is a cross-sectional view illustrating a configuration of the E-E′ cross-section.

In the seventh step, as shown in FIGS. 13A to 13E, a polysilicon film 37 is formed so as to cover the semiconductor materials entirely. The polysilicon film 37 covers the LDD region 9 exposed to the outside. At this time, in a case where the semiconductor device 10 includes a logic section, a circuit element is formed in an area (not illustrated) in which to form the logic section after the storage element area is covered with the polysilicon film 37. In this case, after the steps of forming the circuit element (for example, steps of: forming a well; forming a gate; and forming an extension) are carried out, removed from the storage element area are the oxide film and the polysilicon film which are formed therein at the time of forming the circuit element.

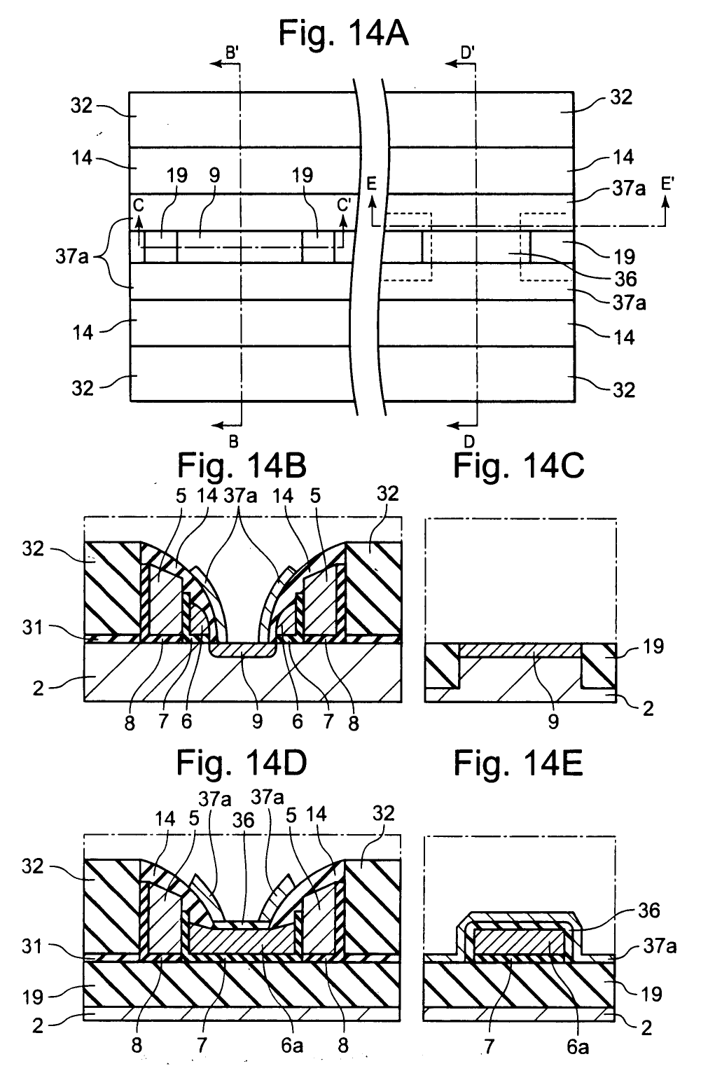

FIGS. 14A to 14E are diagrams illustrating a condition of an eighth step of manufacturing the semiconductor device 10 of the first exemplary embodiment. FIG. 14A is a plan view of semiconductor materials used in the eighth step, which are viewed from above. FIG. 14B is a cross-sectional view illustrating a configuration of the B-B′ cross-section. FIG. 14C is a cross-sectional view illustrating a configuration of the C-C′ cross-section. FIG. 14D is a cross-sectional view illustrating a configuration of the D-D′ cross-section. FIG. 14E is a cross-sectional view illustrating a configuration of the E-E′ cross-section.

In the eighth step, portions of the polysilicon film 37 formed entirely on the semiconductor materials are etched back, and polysilicon sidewalls 37a are thus formed. In the B-B′ cross-section, as shown in FIG. 14B, each polysilicon sidewall 37a is formed in such a way as to cover the side and top surfaces of its corresponding memory gate 6. In addition, a surface of the LDD region 9 between the polysilicon sidewalls 37a is exposed to the outside. In the C-C′ cross-section, as shown in FIG. 14C, the LDD region 9 between the element isolation regions 19 is exposed to the outside. As shown in FIG. 14D, portions of the polysilicon film 37 formed entirely on the semiconductor materials are etched back, and polysilicon sidewalls 37a are thus formed. In the D-D′ cross-section, the polysilicon sidewalls 37a are configured in such a way as to face each other. Thus, a surface of the second protective oxide film 36 between the two polysilicon sidewalls 37a is exposed to the outside. In the E-E′ cross-section, as shown in FIG. 14E, the polysilicon sidewall 37a covers the second protective oxide film 36 on the memory gate contact region 6a.

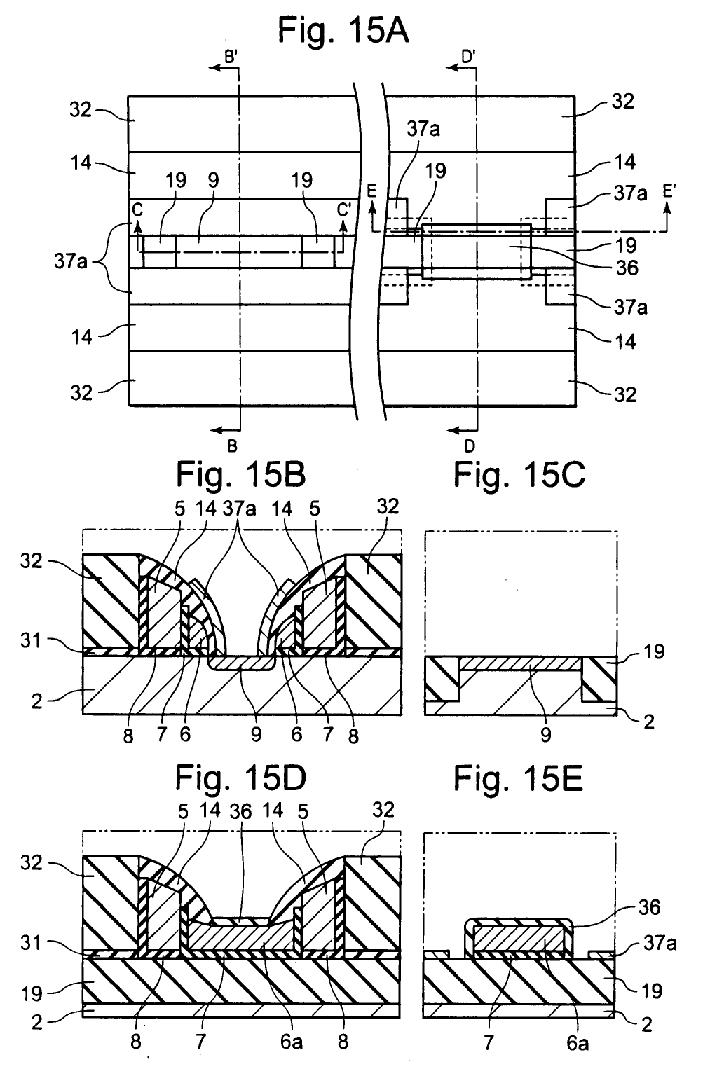

FIGS. 15A to 15E are diagrams illustrating a condition of a ninth step of manufacturing the semiconductor device 10 of the first exemplary embodiment. FIG. 15A is a plan view of semiconductor materials used in the ninth step, which are viewed from above. FIG. 15B is a cross-sectional view illustrating a configuration of the B-B′ cross-section. FIG. 15C is a cross-sectional view illustrating a configuration of the C-C′ cross-section. FIG. 15D is a cross-sectional view illustrating a configuration of the D-D′ cross-section. FIG. 15E is a cross-sectional view illustrating a configuration of the E-E′ cross-section.

In the ninth step, portions of the polysilicon sidewalls 37a in the contact area are removed by use of a resist mask (not illustrated). As shown in FIGS. 15B and 15C, the polysilicon sidewalls 37a in the storage element area are kept in the same condition as those in the eighth step of FIGS. 14A to 14E. In the contact area, as shown in FIG. 15D, in the D-D′ cross-section, the polysilicon sidewalls 37a are removed. In the E-E′ cross-section, as shown in FIG. 15E, the portion of the polysilicon sidewall 37a which has covered the second protective oxide film 36 is removed. At this time, the other portions of the polysilicon sidewall 37a which have been formed respectively at sides of the memory gate contact region 6a are protected by the resist mask. After the portions of the polysilicon sidewalls 37a are removed from the contact area, the resist mask is removed.

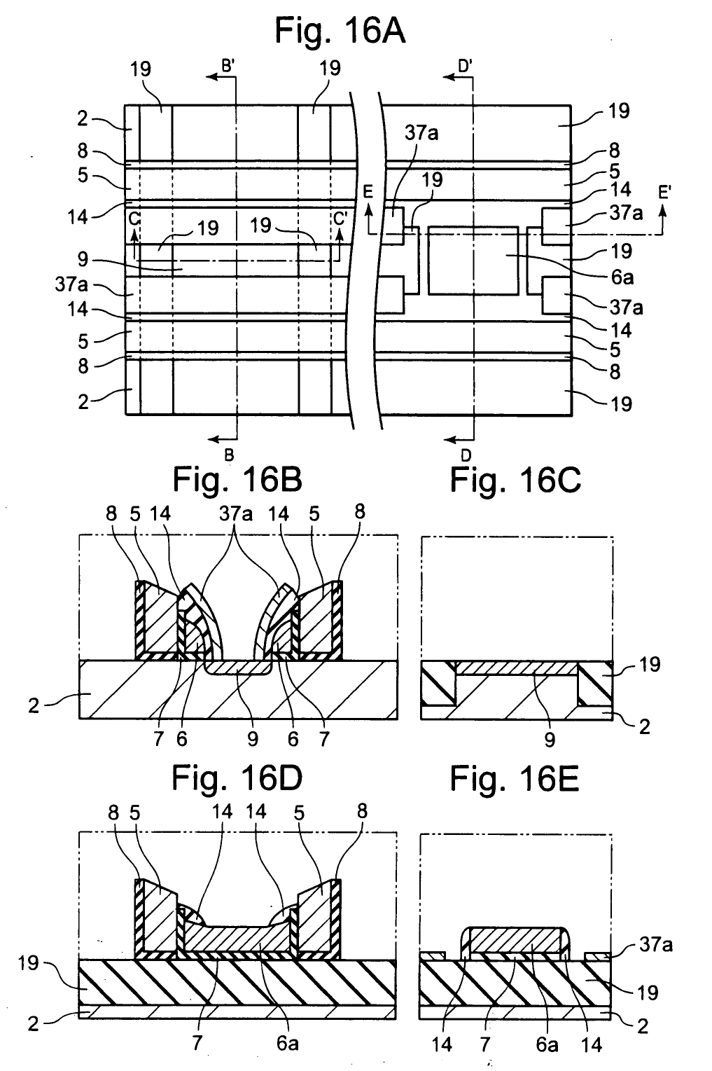

FIGS. 16A to 16E are diagrams illustrating a condition of a tenth step of manufacturing the semiconductor device tenth of the first exemplary embodiment. FIG. 16A is a plan view of semiconductor materials used in the tenth step, which are viewed from above. FIG. 16B is a cross-sectional view illustrating a configuration of the B-B′ cross-section. FIG. 16C is a cross-sectional view illustrating a configuration of the C-C′ cross-section. FIG. 16D is a cross-sectional view illustrating a configuration of the D-D′ cross-section. FIG. 16E is a cross-sectional view illustrating a configuration of the E-E′ cross-section.

In the tenth step, the nitride films 32 are removed with the surface of the LDD region 9 and the surfaces of the respective polysilicon sidewalls 37a being protected by an oxide film (not illustrated). Thereafter, the oxide film and portions of the cell sidewalls 14 on the respective control gates 5 are removed. At this time, a portion of the element isolation region 19 between the adjacent LDD regions 9 may be lowered in some cases. In the case of the first exemplary embodiment, with reference to FIG. 16A, the LDD regions 9 in the adjacent storage elements 1 are connected together by the polysilicon sidewalls 37a. These polysilicon sidewalls 37a are turned into the first diffusion layer-side silicide 11 in the ensuing step. The first diffusion layer-side silicide 11 thus formed electrically connects the first source/drain diffusion layers 3 of the respective adjacent storage elements 1 together. For this reason, the storage elements 1 can be formed while not affected by the height of each element isolation region 19.

In the tenth step, as shown in FIG. 16B, in the B-B′ cross-section, the top surfaces of the control gates 5 and surfaces of the semiconductor substrate 2 at outer sides of the control gates 5 are exposed to the outside, respectively. In the C-C′ cross-section, as shown in FIG. 16C, the surface of the LDD region 9 having been temporarily covered with the oxide film (not illustrated) is exposed to the outside. In the D-D′ cross-section, as shown in FIG. 16D, the top surfaces of the control gates 5, a surface of the memory gate contact region 6a, and surfaces of the element isolation region 19 at outer sides of the control gates 5 are exposed to the outside, respectively. In the tenth step, as shown in FIG. 16E, in the E-E′ cross-section, the cell sidewalls 14 each formed in a sidewall shape are formed on the side surfaces of the memory gate contact region 6a, respectively.

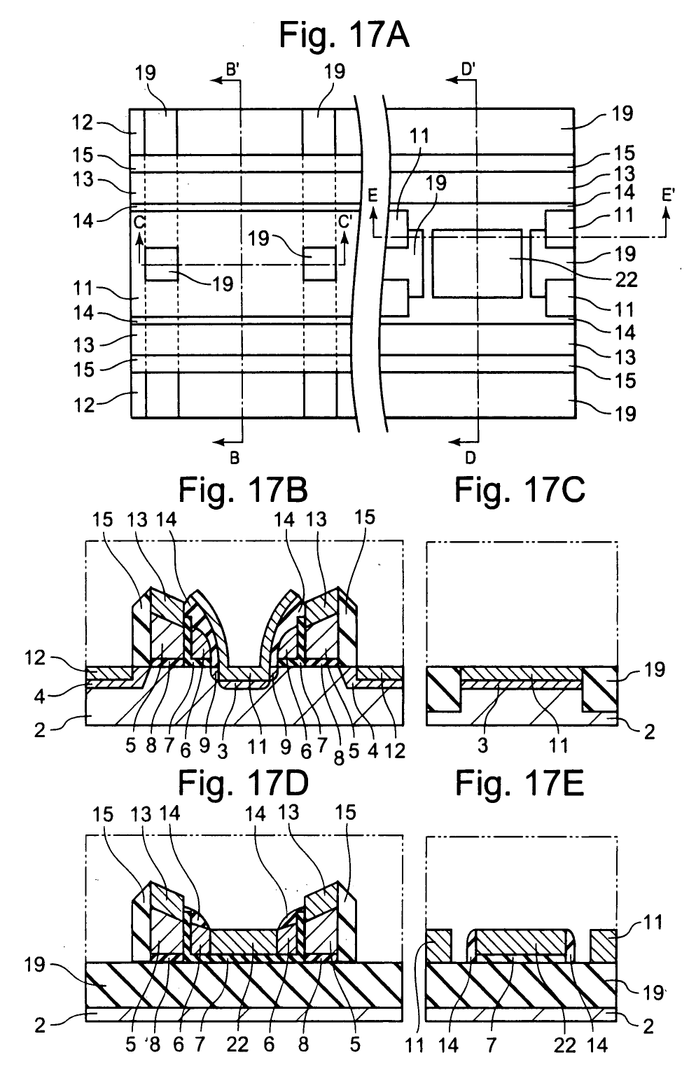

FIGS. 17A to 17E are diagrams illustrating a condition of an eleventh step of manufacturing the semiconductor device 10 of the first exemplary embodiment. FIG. 17A is a plan view of semiconductor materials used in the eleventh step, which are viewed from above. FIG. 17B is a cross-sectional view illustrating a configuration of the B-B′ cross-section. FIG. 17C is a cross-sectional view illustrating a configuration of the C-C′ cross-section. FIG. 17D is a cross-sectional view illustrating a configuration of the D-D′ cross-section. FIG. 17E is a cross-sectional view illustrating a configuration of the E-E′ cross-section.

In the eleventh step, as shown in FIGS. 17B and 17C, to form the first source/drain diffusion layer 3 and the second source/drain diffusion layers 4, impurities (for example, As with a concentration of 2E15/cm²) are implanted, with the memory gates 6 or the control gates 5 functioning as masks. Subsequently, the polysilicon sidewalls 37a and a portion of the first source/drain diffusion layer 3 therebetween are silicided, and are thus made into the first diffusion layer-side silicide 11. At this time, together with this formation, the second diffusion layer-side silicides 12 and the control gate silicides 13 are formed. In the eleventh step, as shown in FIGS. 17D and 17E, in the contact area, the memory gate silicide 22 is formed.

Thereafter, the sidewalls 15 are formed. Subsequently, the interlayer insulating film 18 (not illustrated) is configured. Afterward, the contact hole (not illustrated) in which to form the first source/drain contact 16 and the contact holes (not illustrated) in which to form the respective second source/drain contacts 17 are configured.

### Second Exemplary Embodiment

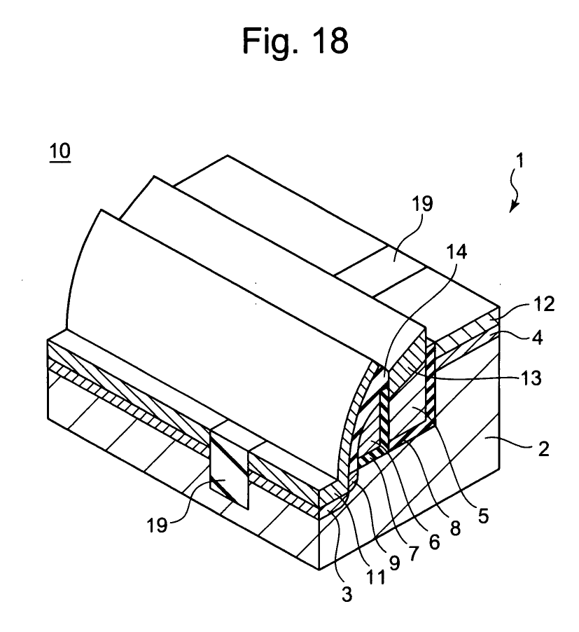

Referring to the drawings, descriptions will be hereinafter provided for a second exemplary embodiment of the present invention. FIG. 18 is a perspective view illustrating a three-dimensional configuration of a storage element 1 included in a semiconductor device 10 of the second exemplary embodiment. The semiconductor device 10 includes multiple storage elements 1. Each of the multiple storage elements 1 includes a first source/drain diffusion layer 3 and a second source/drain diffusion layer 4. The first source/drain diffusion layer 3 and the second source/drain diffusion layer 4 are formed in a semiconductor substrate 2. The storage element 1 includes a control gate 5 and a memory gate 6 which are adjacent to each other with a charge-storage layer (ONO layer) 7 interposed in between. An LDD region 9 is provided in the semiconductor substrate 2 between the first source/drain diffusion layer 3 and the memory gate 6.

The control gate 5 and the memory gate 6 of the second exemplary embodiment are provided inside a trench formed in the semiconductor substrate 2. In addition, the first source/drain diffusion layer 3 is provided inside the trench, whereas the second source/drain diffusion layer 4 is provided outside the trench.

A gate insulating film 8 is provided between the control gate 5 and the semiconductor substrate 2. The gate insulating film 8 is provided on a side surface of the control gate 5 at a side closer to the second source/drain diffusion layer 4 as well. The charge-storage layer 7 is provided between the memory gate 6 and the semiconductor substrate 2. The charge-storage layer 7 is provided between the memory gate 6 and the control gate 5 as well. In addition, a control gate silicide 13 is provided on the control gate 5. A second diffusion layer-side silicide 12 is provided on the second source/drain diffusion layer 4. A cell sidewall 14 is provided along the side surface of the memory gate 6 up to the top surface thereof, the side surface being located closer to the first source/drain diffusion layer 3. In addition, a first diffusion layer-side silicide 11 is provided along the cell sidewall 14 in such a way as to cover the top and side surfaces of the memory gate 6.

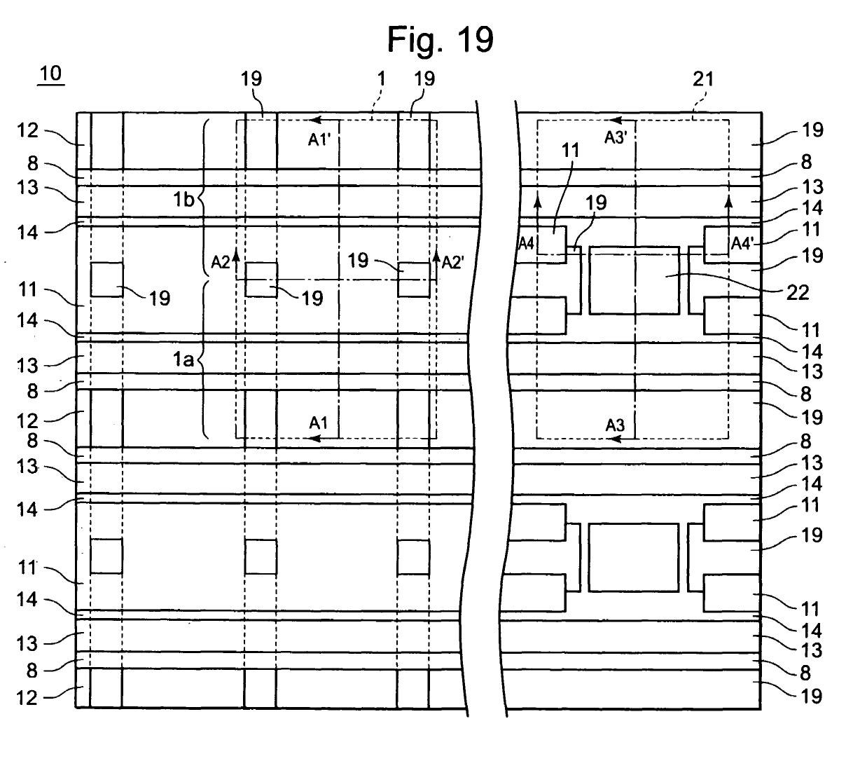

FIG. 19 is a plan view illustrating a configuration of the semiconductor device 10 of the second exemplary embodiment which is viewed from above. Interconnections and via contacts are omitted from the plan view of FIG. 19 so as to facilitate understanding of the present invention filed for the patent application. With reference to FIG. 19, each of the multiple storage elements 1 included in the semiconductor 10 includes two memory cells (a first memory cell 1a and a second memory cell 1b). The first memory cell 1a and the second memory cell 1b have the same configuration, and are symmetrical with each other. With this taken into consideration, duplicate descriptions will be hereinbelow omitted with regard to the first memory cell 1a and the second memory cell 1b. Furthermore, in the following descriptions of the second exemplary embodiment, one of the two memory cells may be specified. In this case, the specified memory cell corresponds to the first memory cell 1a, and configurations and operations thereof will be described.

The semiconductor device 10 includes: storage element areas, whose storage elements 1 are arranged in an array; and contact areas 21, in each of which a contact (not illustrated) connected to the memory gate 6 is formed. Each storage element area includes the first source/drain contact 16 (not illustrated) connected to the first diffusion layer-side silicide 11, and the second source/drain contacts 17 (not illustrated) connected to the respective diffusion layer-side silicides 12. As shown in FIG. 19, the multiple storage elements 1 arranged in the semiconductor device 10 are separated from one another by the corresponding element isolation regions 19 each extending in a first direction. The gates (the control gate 5 and the memory gate 6) of each of the multiple storage elements 1 are provided along a second direction orthogonal to the first direction. In addition, each contact area 21 is provided in such a way as to include the element isolation region 19. As shown in FIG. 19, each contact area 21 includes a memory gate silicide 22. The memory gate silicide 22 is configured above the element isolation region 19. A memory gate contact 23 (not illustrated) to be described later is connected to the memory gate silicide 22.

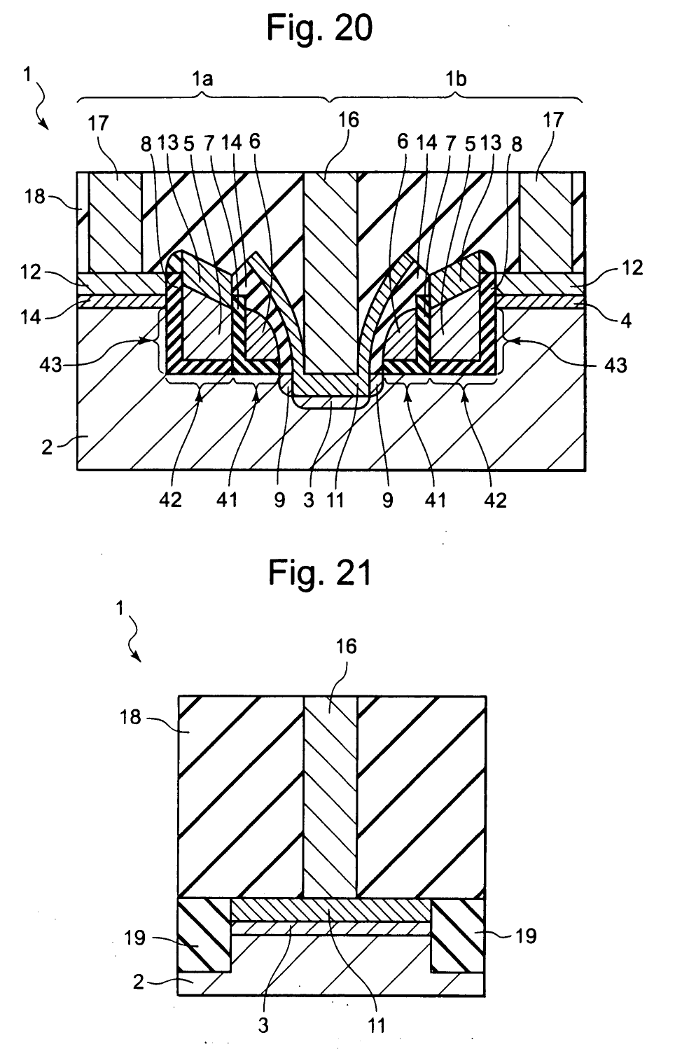

FIG. 20 is a cross-sectional view illustrating a configuration of a cross-section of the storage element 1 of the second exemplary embodiment, which is taken along the line A1-A1′ of FIG. 19. As shown in FIG. 20, the storage element 1 of the second exemplary embodiment includes the first source/drain diffusion layer 3 configured inside the trench, and the second source/drain diffusion layers 4 configured outside the trench. The control gates 5 and the memory gates 6 are provided inside the trench.

A first channel region 41, a second channel region 42 and a third channel region 43 are provided between the first source/drain diffusion layer 3 and each second source/drain diffusion layer 4. The first channel region 41 is located under each memory gate 6, the second channel region 42 is located under each control gate 5, and the third channel region 43 is located on the side surface of each control gate 5. The side surfaces of the control gates 5 face the side surfaces of the trench with portions of the gate insulating films 8 interposed therebetween, respectively, the portions of the gate insulating films 8 configured in a vertical direction. The first source/drain diffusion layer 3 is connected to the first source/drain contact 16 with the first diffusion layer-side silicide 11 interposed in between. The first diffusion layer-side silicide 11 is configured in such a way as to cover the side and top surfaces of each memory gate 6 with the corresponding cell sidewall 14 interposed in between. The first diffusion layer-side silicide 11 is connected to the first source/drain diffusion layer 3 with no polysilicon interposed in between.

In addition, the sidewalls are provided on side surfaces of the control gate silicides 13, respectively, and the side surfaces are located respectively at sides closer to the second source/drain diffusion layers 4. The second diffusion layer-side silicides 12 are provided on the second source/drain diffusion layers 4 located at outer sides of the sidewalls, respectively. The second source/drain diffusion layers 4 are connected to the second source/drain contacts 17 with the second diffusion layer-side silicides 12 interposed therebetween, respectively.

FIG. 21 is a cross-sectional view illustrating a configuration of another cross-section of the storage element 1 of the second exemplary embodiment which is taken along the line A2-A2′ of FIG. 19. As shown in FIG. 21, the first source/drain diffusion layer 3 is provided in the semiconductor substrate 2 between the adjacent element isolation regions 19. Similarly to the source/drain diffusion layer 3, the first diffusion layer-side silicide 11 is provided between the element isolation regions 19. The first source/drain contact 16 is provided in a contact hole penetrating an interlayer insulating film 18.

FIG. 22 is a cross-sectional view illustrating a configuration of a cross-section of the contact area 21, which is taken along the A3-A3′ of FIG. 19. In the contact area 21 of the second exemplary embodiment, the memory gate silicide 22 is provided inside the trench as shown in FIG. 22. The contact area 21 has a symmetrical configuration as in the case of the first exemplary embodiment.

The contact area 21 is provided on the element isolation region 19 formed on the semiconductor substrate 2. The memory gate silicide 22 of the contact area 21 is connected to the two gate memory gates 6 facing each other. One of the two memory gates 6 is connected to the memory gate 6 of the first memory cell 1a. The other of the two memory gates 6 is connected to the memory gate 6 of the second memory cell 1b. The top surfaces of the memory gates 6 included in the contact area 21 are covered with the cell sidewalls 14, respectively. The charge-storage layer 7 is configured between each memory gate 6 and the element isolation region 19. The charge-storage layer 7 is provided between the memory gate silicide 22 and the element isolation region 19 as well. The memory gate contact 23 connected to the memory gate silicide 22 is provided in a contact hole penetrating the interlayer insulating film 18.

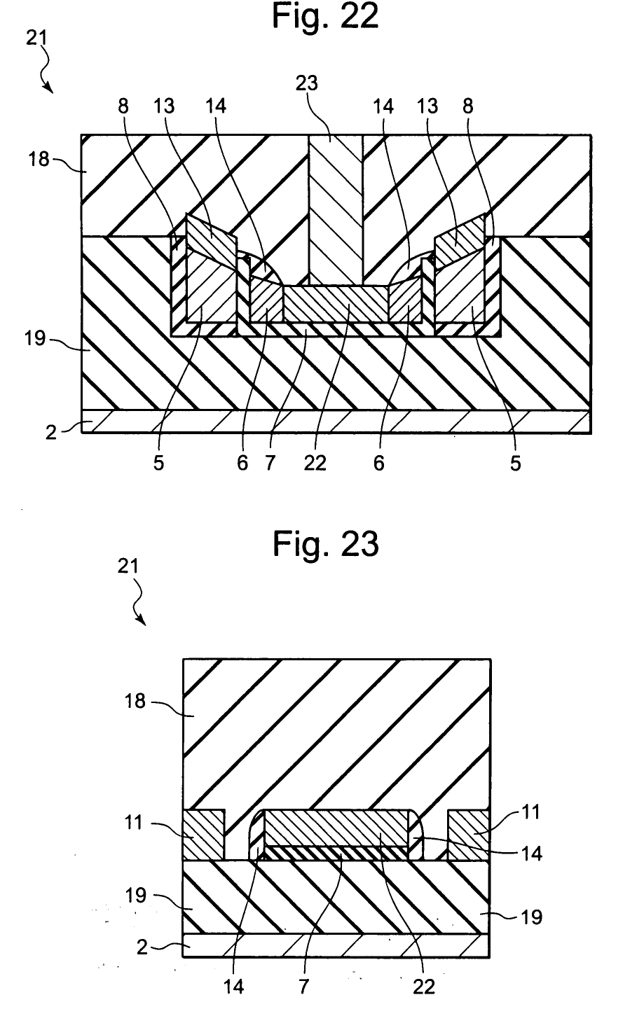

FIG. 23 is across-sectional view illustrating a configuration of another cross-section of the contact area 21, of the second exemplary embodiment, which is taken along the line A4-A4′ of FIG. 19. In the contact area 21, as shown in FIG. 23, the cell sidewalls 14 are provided on the side surfaces of the memory gate silicide 22, respectively.

As described above, the storage element 1 of the second exemplary embodiment includes the control gates 5 inside the trench configured in the semiconductor substrate 2, and the second source/drain diffusion layers 4 configured outside the trench. Steps are formed between the control gates 5 and the second source/drain diffusion layers 4, respectively. The thus-formed side surfaces of the trench are caused to function as channel regions. This makes the gate lengths sufficient enough for the control gates 5 to suppress the occurrence of their malfunctions even when the substantial widths of the control gates 5 are reduced.

In order to read information from the storage element 1 at high speed, it is desirable that the difference (or the ratio) between the current flowing in the written state and the current flowing in the erased state is large. In the second exemplary embodiment, as described above, the first source/drain contact 16 is connected to the first diffusion layer-side silicide 11, which is connected to the first source/drain diffusion layer 3 with no polysilicon interposed in between. This makes it possible to suppress an increase in the resistance between the first source/drain contact 16 and the first source/drain diffusion layer 3 in response to the miniaturization of the memory cells. In addition, by increasing the amount of current to flow in the storage element 1 of the second exemplary embodiment in the erased state (ON current), it is possible to configure the memory cells capable of performing high speed operations with their areas decreased.

In the case of the storage element 1 of the second exemplary embodiment, the side surfaces of the trench are provided as channel regions respectively corresponding to the control gates 5. In other words, the side surfaces of the trench are provided in such a way as not to be affected by the memory gates 6, respectively. This makes it possible to reduce the length of the channel region under each memory gate 6, and thus to secure a larger amount of ON current for the channel region, in the storage element 1 of the second exemplary embodiment.

In addition, the storage element 1 of the second exemplary embodiment has the memory gates 6 and the charge-storage layers 7 inside the trench. This makes it possible to prevent punch-through from occurring to the first source/drain diffusion layer 3 through deeper portions of the channels under the memory gates 6 even if the channel regions under the control regions 5 are fully inverted. For this reason, in the storage element 1 of the second exemplary embodiment, it is possible to thin down (e.g., reduce) the substantial width of each memory gate 6, and accordingly to reduce the area used for each memory cell.

Moreover, the first diffusion layer-side silicide 11 covers the top and side surfaces of each memory gate 6 along its corresponding cell sidewall 14. Accordingly, like the storage element 1 of the first exemplary embodiment, the storage element 1 of the second exemplary embodiment is capable of preventing the occurrence of failure such as a short circuit between each memory gate 6 and the first source/drain diffusion layer 3 even in a case where the position of the contact hole in which to form the first source/drain contact IS 16 deviates from its designed position in making the contact hole.

Descriptions will be hereinbelow provided for a process for manufacturing the semiconductor device 10 of the second exemplary embodiment. The semiconductor device 10 of the second exemplary embodiment includes multiple storage elements 1 and contact areas 21. The storage elements 1 and the contact areas 21 are formed simultaneously. In addition, each storage element 1 is arranged in a position away from its corresponding contact area 21. Hereinbelow, descriptions will be provided for the process for manufacturing the semiconductor device 10, while the interstices between the areas (hereinafter, described as “storage element areas”) in which the storage elements 1 are formed and the respective contact areas 21 are omitted.

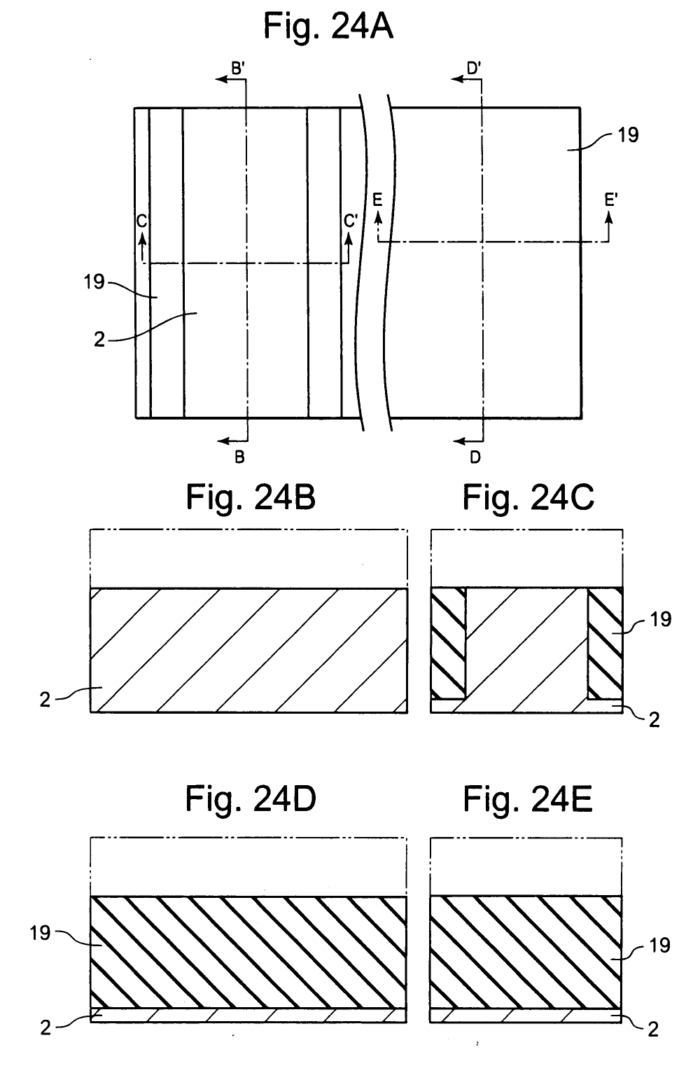

FIGS. 24A to 24E are diagrams illustrating a condition of a first step of manufacturing the semiconductor device 10 of the second exemplary embodiment. FIG. 24A is a plan view of semiconductor materials used in the first step, which are viewed from above. FIG. 24B is a cross-sectional view illustrating a cross-section (hereinafter described as a “B-B′ cross-section”) of the semiconductor materials, which is taken along the line B-B′ of FIG. 24A. FIG. 24C is a cross-sectional view illustrating a cross-section (hereinafter described as a “C-C′ cross-section”) of the semiconductor materials, which is taken along the line C-C′ of FIG. 24A. FIG. 24D is a cross-sectional view illustrating a cross-section (hereinafter described as a “D-D′ cross-section”) of the semiconductor materials, which is taken along the line D-D′ of FIG. 24A. FIG. 24E is a cross-sectional view illustrating a cross-section (hereinafter described as a “E-E′ cross-section”) of the semiconductor materials, which is taken along the line E-E′ of FIG. 24A. In the first step, as shown in FIGS. 24A to 24E, the element isolation regions 19 are formed in the semiconductor substrate 2.

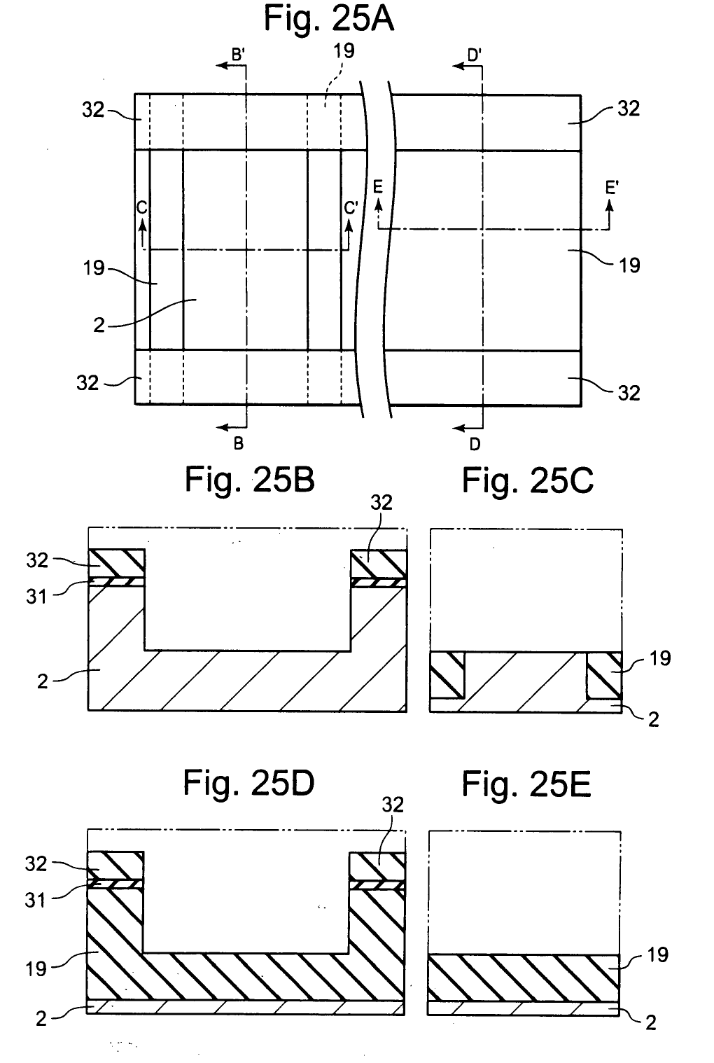

FIGS. 25A to 25E are diagrams illustrating a condition of a second step of manufacturing the semiconductor device 10 of the second exemplary embodiment. FIG. 25A is a plan view of semiconductor materials used in the second step, which are viewed from above. FIG. 25B is a cross-sectional view illustrating a configuration of the B-B′ cross-section. FIG. 25C is a cross-sectional view illustrating a configuration of the C-C′ cross-section. FIG. 25D is a cross-sectional view illustrating a configuration of the D-D′ cross-section. FIG. 25E is a cross-sectional view illustrating a configuration of the E-E′ cross-section.

As shown in FIGS. 25A to 25E, an oxide film 31 and a nitride film 32 are sequentially formed in such a way as to cover the element isolation regions 19 and the semiconductor substrate 2. Thereafter, a resist having a predetermined pattern is formed on the nitride film 32. Afterward, portions respectively of the nitride film 32 and the oxide film 31 are removed by using the resist as a mask.

In the second step, as shown in FIG. 25B, in the storage element area, an opening portion is made between the remaining portions of the nitride film 32. Subsequently, the trench is formed in a portion of the semiconductor substrate 2, which corresponds to the opening portion. Furthermore, in the second step, as shown in FIG. 25C, in the storage element area, the element isolation regions 19 are shaved (e.g., reduced) in order that the height of each element isolation region 19 should be equal to that of the exposed portion of the semiconductor substrate 2. At this time, in the contact area, a trench is formed in the element isolation region 19, like in the semiconductor substrate 2. Consequently, as shown in FIGS. 25D and 25(e), the element separating region 19 having the trench in the opening portion between the remaining portions of the nitride film 32 is formed in the contact area.

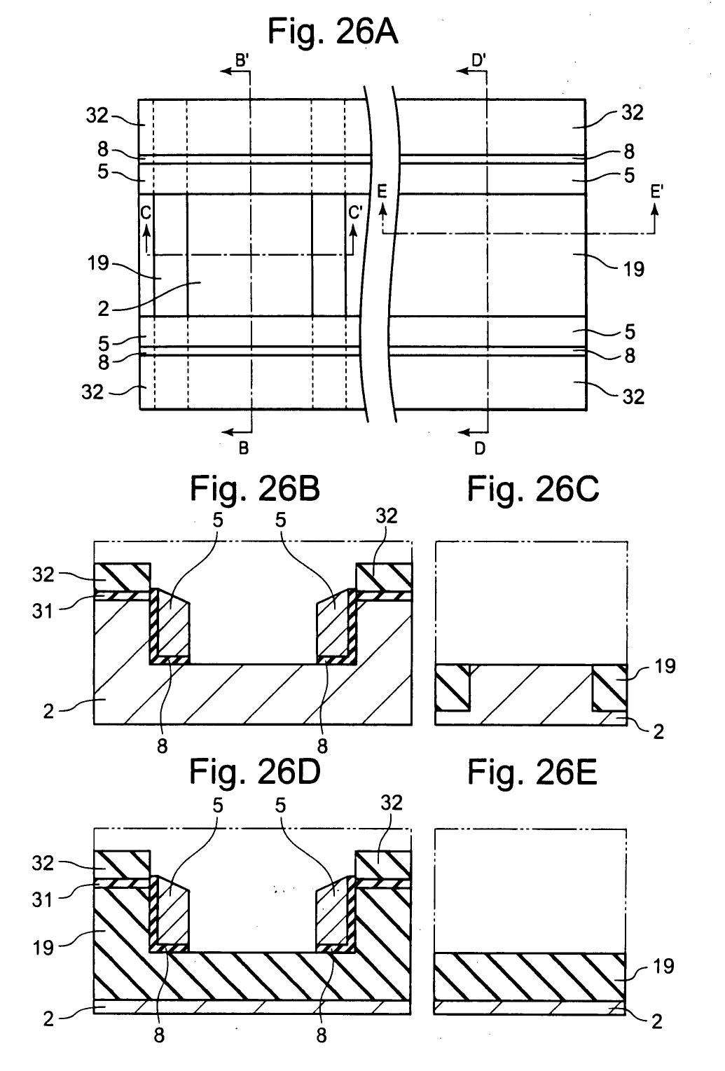

FIGS. 26A to 26E are diagrams illustrating a condition of a third step of manufacturing the semiconductor device 10 of the second exemplary embodiment. FIG. 26A is a plan view of semiconductor materials used in the third step, which are viewed from above. FIG. 26B is a cross-sectional view illustrating a configuration of the B-B′ cross-section. FIG. 26C is a cross-sectional view illustrating a configuration of the C-C′ cross-section. FIG. 26D is a cross-sectional view illustrating a configuration of the D-D′ cross-section. FIG. 26E is a cross-sectional view illustrating a configuration of the E-E′ cross-section.

In the third step, an oxide film which will serve as the gate insulating films 8 is formed on the surface of the semiconductor substrate 2 in the trench and the surfaces of the respective nitride films 32. Subsequently, a polysilicon film which will serve as the control gates 5 is formed on the oxide film. Thereafter, the polysilicon is etched back, and the control gates 5 each formed in a sidewall shape are thus formed. Afterward, an unnecessary portion of the oxide film is removed, and the gate insulating films 8 are thus formed.

In the third step, as shown in FIGS. 26B and 26C, in the storage element area, the control gates 5 and the gate insulating films 8 are formed inside the trench. In addition, the semiconductor substrate 2 between the control gates 5 facing each other is exposed to the outside. Furthermore, in the third step, as shown in FIGS. 26D and 26E, in the contact area, the control gates 5 and the gate insulating films 8 are formed inside the trench, and the element isolation region 19 between the control gates 5 facing each other is exposed to the outside.

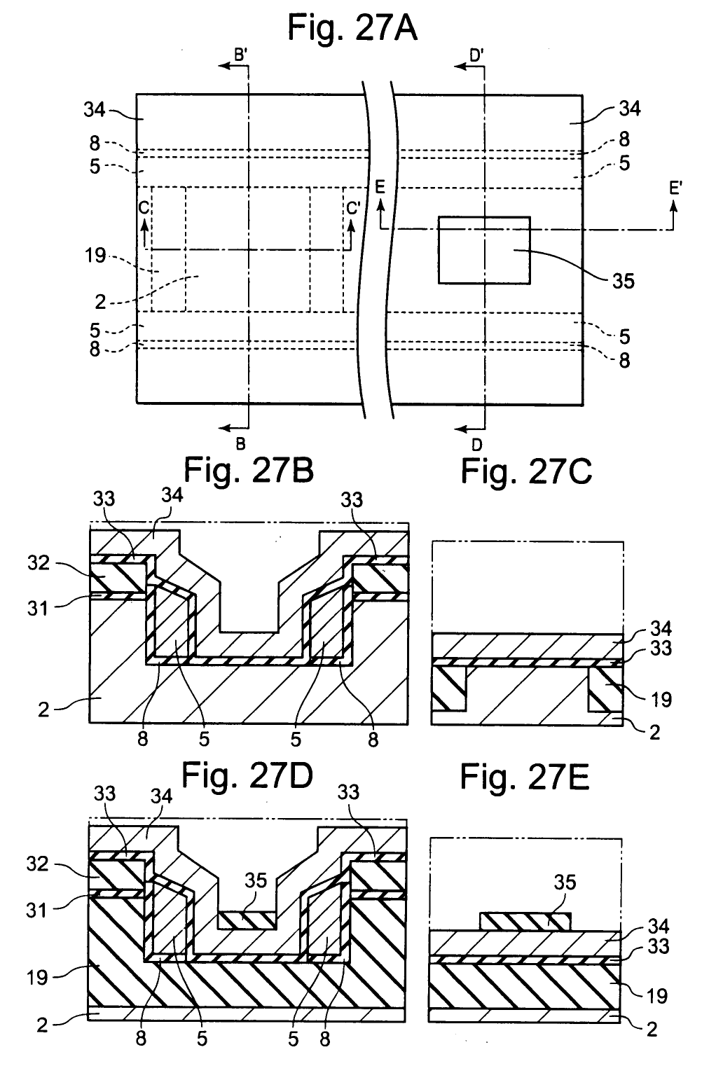

FIGS. 27A to 27E are diagrams illustrating a condition of a fourth step of manufacturing the semiconductor device 10 of the second exemplary embodiment. FIG. 27A is a plan view of semiconductor materials used in the fourth step, which are viewed from above. FIG. 27B is a cross-sectional view illustrating a configuration of the B-B′ cross-section. FIG. 27C is a cross-sectional view illustrating a configuration of the C-C′ cross-section. FIG. 27D is a cross-sectional view illustrating a configuration of the D-D′ cross-section. FIG. 27E is a cross-sectional view illustrating a configuration of the E-E′ cross-section.

In the fourth step, as shown in FIGS. 27A to 27E, a charge-storage film (ONO film) 33 which will serve as the charge-storage layers 7 is formed. Thereafter, a memory gate polysilicon film 34 which will serve as the memory gates 6 is formed on the charge-storage film (ONO film) 33. In the fourth step, as shown in FIG. 27A, in the contact area, a first protective oxide film 35 is further formed on the memory gate polysilicon film 34.

In the B-B′ cross-section of the storage element area, as shown in FIG. 27B, the charge-storage film (ONO film) 33 is formed so as to cover the exposed surface of the semiconductor substrate 2 inside the trench, the exposed side and top surfaces of each control gate 5, and the exposed side and top surfaces of each nitride film 32. Subsequently, the memory gate polysilicon film 34 is formed on the charge-storage film (ONO film) 33. The memory gate polysilicon film 34 is formed in such a way as to include an opening portion. In the C-C′ cross-section, as shown in FIG. 27C, the charge-storage film (ONO film) 33 and the memory gate polysilicon film 34 are formed on the element isolation regions 19 as well.

In the D-D′ cross-section of the contact area, as shown in FIG. 27D, the charge-storage film (ONO film) 33 is formed so as to cover the exposed surface of the element isolation region 19 inside the trench, the exposed side and top surfaces of each control gate 5, and the exposed side and top surfaces of each nitride film 32. Subsequently, the memory gate polysilicon film 34 is formed on the charge-storage film (ONO film) 33. The memory gate polysilicon film 34 is formed in such a way as to include an opening portion. The first protective oxide film 35 is formed in such a way as to cover the bottom surface of the opening portion. As shown in FIG. 27E, the first protective oxide film 35 is formed on a position corresponding to a position in which the memory gate silicide 22 is be made in the ensuing step.

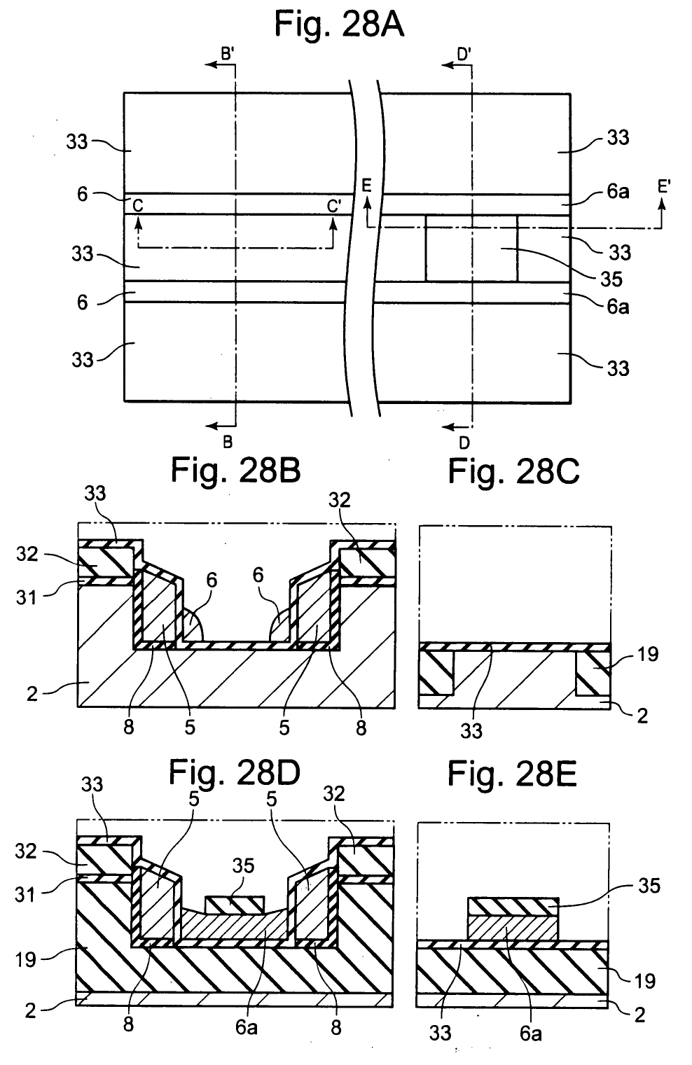

FIGS. 28A to 28E are diagrams illustrating a condition of a fifth step of manufacturing the semiconductor device 10 of the second exemplary embodiment. FIG. 28A is a plan view of semiconductor materials used in the fifth step, which are viewed from above. FIG. 28B is a cross-sectional view illustrating a configuration of the B-B′ cross-section. FIG. 28C is a cross-sectional view illustrating a configuration of the C-C′ cross-section. FIG. 28D is a cross-sectional view illustrating a configuration of the D-D′ cross-section. FIG. 28E is a cross-sectional view illustrating a configuration of the E-E′ cross-section.

In the fifth step, as shown in FIGS. 28A to 28E, the memory gate polysilicon film 34 is etched back, and the memory gates 6 are thus formed. In the B-B′ cross-section of the storage element area, as shown in FIG. 28B, the memory gates 6 are formed inside the trench in such a way as to face each other. The charge-storage film (ONO film) 33 between the memory gates 6 facing each other is exposed to the outside. In the C-C′ cross-section, as shown in FIG. 28C, the charge-storage film (ONO film) 33 remains, thereby covering the surfaces of the element isolation regions 19 and the semiconductor substrate 2.

In the D-D′ cross-section of the contact area, as shown in FIG. 28D, a residual portion of the memory gate polysilicon film 34 which will serve as a memory gate contact region 6a remains on a side of each control gate 5 and under the first protective oxide film 35 in the inside of the trench. In the E-E′ cross-section, as shown in FIG. 28E, the memory gate contact region 6a is made under the first protective oxide film 35.

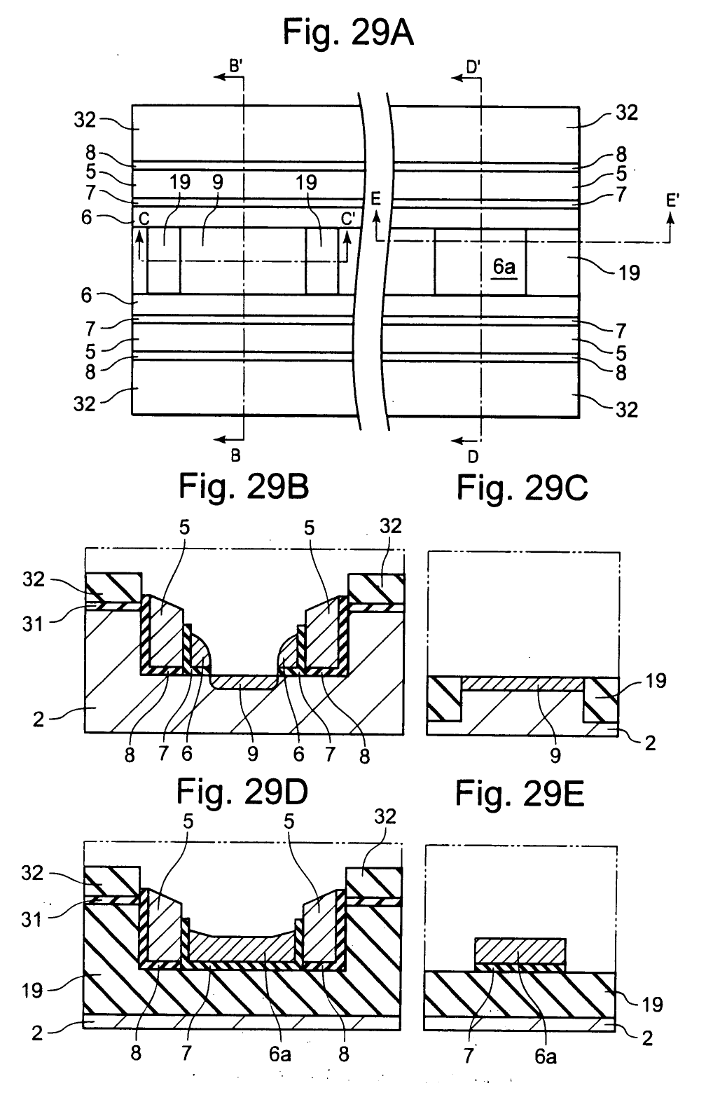

FIGS. 29A to 29E are diagrams illustrating a condition of a sixth step of manufacturing the semiconductor device 10 of the second exemplary embodiment. FIG. 29A is a plan view of semiconductor materials used in the sixth step, which are viewed from above. FIG. 29B is a cross-sectional view illustrating a configuration of the B-B′ cross-section. FIG. 29C is a cross-sectional view illustrating a configuration of the C-C′ cross-section. FIG. 29D is a cross-sectional view illustrating a configuration of the D-D′ cross-section. FIG. 29E is a cross-sectional view illustrating a configuration of the E-E′ cross-section.

In the sixth step, as shown in FIGS. 29A to 29E, a portion of the charge-storage film (ONO film) 33 provided between the memory gates 6 facing each other inside the trench is removed. Thereby, the charge-storage layers 7 are formed under the respective memory gates 6. Subsequently, impurities (for example, As with a concentration of approximately 14/cm²) are implanted into the exposed portion of the semiconductor substrate 2. Thereby, a diffusion layer which will serve as the LDD region 9 is formed in a bottom surface of the trench. At this time, in the contact area, the first protective oxide film 35 made on the memory gate contact region 6a is removed.

In the sixth step, as shown in FIG. 29B, in the B-B′ cross-section, the charge-storage film (ONO film) 33 covering the control gates 5 and the nitride films 32 is removed. At this time, a portion of the charge-storage film (ONO film) 33 remains between each control gate 5 and its corresponding memory gate 6, and thus electrically insulates the control gate 5 and the memory gate 6. In the C-C′ cross-section, as shown in FIG. 29C, the LDD region 9 is formed between the element isolation regions 19. In the D-D′ cross-section, as shown in FIG. 29D, the first protective oxide film 35 is removed, and the surface of the memory gate contact region 6a is thus exposed to the outside. In addition, a portion of the charge-storage film (ONO film) 33 which covers the control gates 5 and the nitride films 32 is removed with another portion of the charge-storage film (ONO film) 33 remaining underlying the memory gate contact region 6a. Thereby, the charge-storage layer 7 is formed. In the E-E′ cross-section, as shown in FIG. 29E, the first protective oxide film 35 and portions of the charge-storage film (ONO film) 33 are removed. Thereby, surfaces of the element isolation region 19 are exposed to the outside.

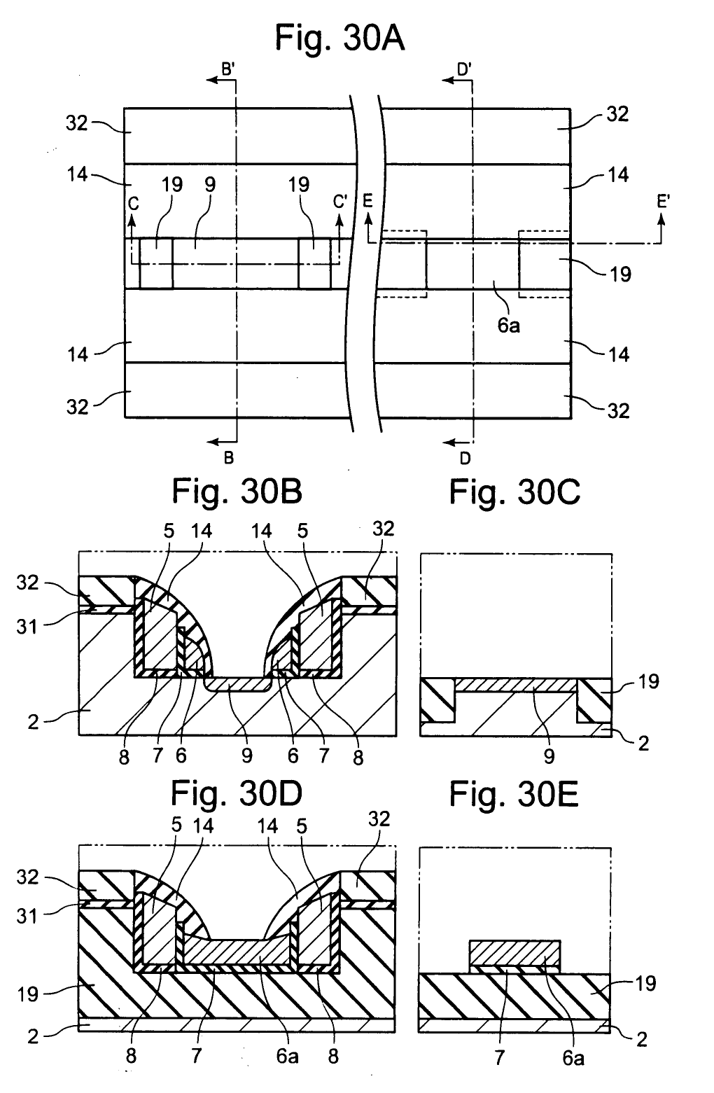

FIGS. 30A to 30E are diagrams illustrating a condition of a seventh step of manufacturing the semiconductor device 10 of the second exemplary embodiment. FIG. 30A is a plan view of semiconductor materials used in the seventh step, which are viewed from above. FIG. 30B is a cross-sectional view illustrating a configuration of the B-B′ cross-section. FIG. 30C is a cross-sectional view illustrating a configuration of the C-C′ cross-section. FIG. 30D is a cross-sectional view illustrating a configuration of the D-D′ cross-section. FIG. 30E is a cross-sectional view illustrating a configuration of the E-E′ cross-section.

In the seventh step, as shown in FIGS. 30A to 30E, an oxide film (not illustrated) is formed so as to cover the semiconductor materials entirely. Thereafter, the cell sidewalls 14 are formed by etching back the oxide film. In the seventh step, as shown in FIG. 30B, in the B-B′ cross-section, the side and top surfaces of each memory gate 6 and the top surface of each control gate 5 are covered with a corresponding one of the cell sidewalls 14. In the B-B′ cross-section, the cell sidewalls 14 are made in such a way as to face each other. As shown in FIG. 30C, the C-C′ cross-section corresponds to the opening portion between the cell sidewalls 14 facing each other, in which the LDD region 9 between the element isolation regions 19 is exposed to the outside.

In the seventh step, as shown in FIG. 30D, in the D-D′ cross-section, portions of the memory gate contact region 6a and the top surfaces of the control gates 5 are covered with the cell sidewalls 14, respectively. The cell sidewalls 14 have an opening portion therebetween, and are configured in such a way as to face each other. In the seventh step, as shown in FIG. 30E, the top surface of the memory gate contact region 6a is exposed to the outside.

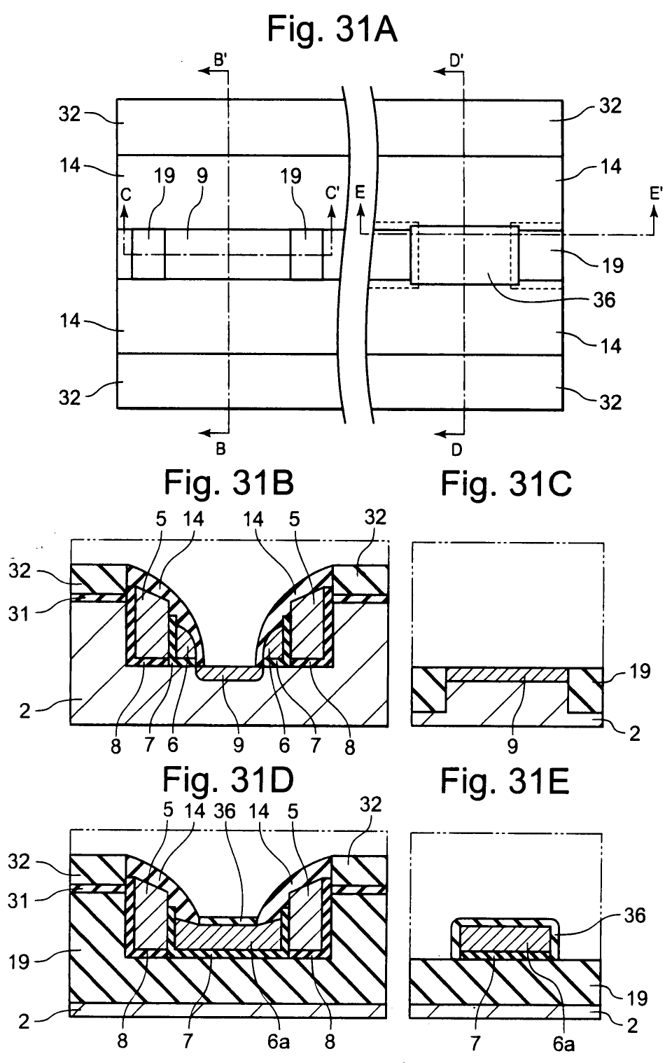

FIGS. 31A to 31E are diagrams illustrating a condition of an eighth step of manufacturing the semiconductor device 10 of the second exemplary embodiment. FIG. 31A is a plan view of semiconductor materials used in the eighth step, which are viewed from above. FIG. 31B is a cross-sectional view illustrating a configuration of the B-B′ cross-section. FIG. 31C is a cross-sectional view illustrating a configuration of the C-C′ cross-section. FIG. 31D is a cross-sectional view illustrating a configuration of the D-D′ cross-section. FIG. 31E is a cross-sectional view illustrating a configuration of the E-E′ cross-section.

In the eighth step, in the contact region, a second protective oxide film 36 is formed so as to cover the memory gate contact region 6a between the cell sidewalls 14 facing each other. In the B-B′ cross-section, as shown in FIG. 31B, the surface of the LDD region 9 is exposed to the outside. In the C-C′ cross-section, as shown in FIG. 31C, the surface of the LDD region 9 is exposed to the outside. In the D-D′ cross-section, as shown in FIG. 31D, the second protective oxide film 36 is formed so as to cover a surface of the memory gate contact region 6a inside the trench. In the eighth step, as shown in FIG. 31E, in the E-E′ cross-section, the second protective oxide film 36 is formed so as to cover the top and side surfaces of the memory gate contact region 6a. In addition, the second protective oxide film 36 covers the side surfaces of the charge-storage layer 7 formed under the memory gate contact region 6a.

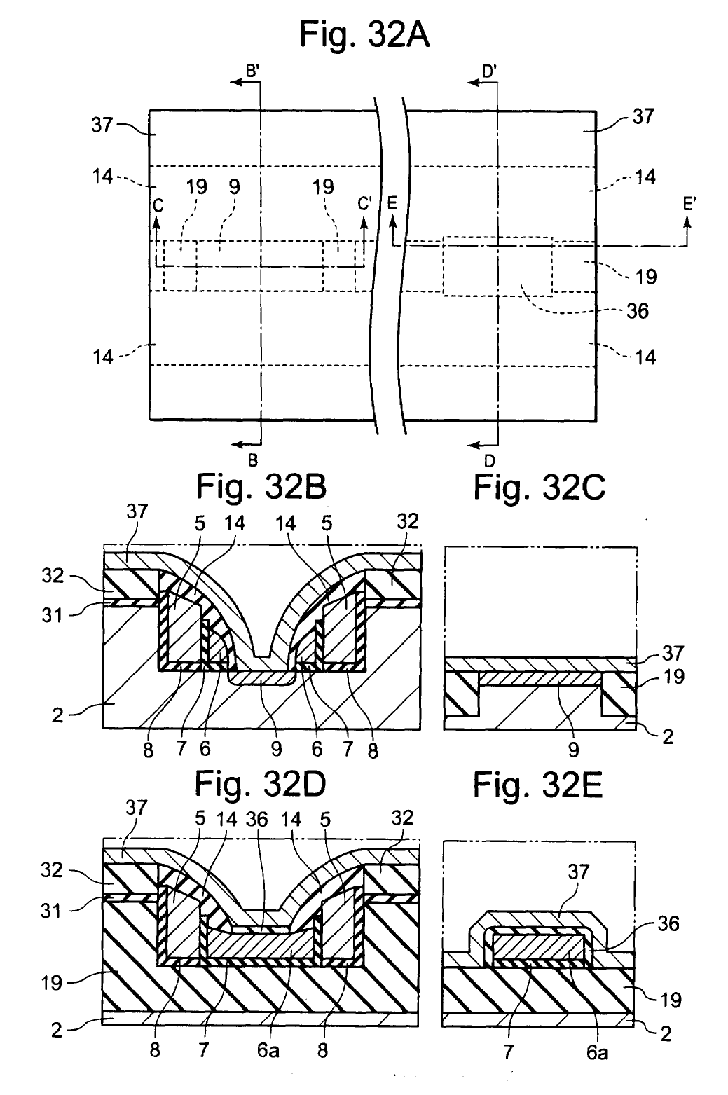

FIGS. 32A to 32E are diagrams illustrating a condition of a ninth step of manufacturing the semiconductor device 10 of the second exemplary embodiment. FIG. 32A is a plan view of semiconductor materials used in the ninth step, which are viewed from above. FIG. 32B is a cross-sectional view illustrating a configuration of the B-B′ cross-section. FIG. 32C is a cross-sectional view illustrating a configuration of the C-C′ cross-section. FIG. 32D is a cross-sectional view illustrating a configuration of the D-D′ cross-section. FIG. 32E is a cross-sectional view illustrating a configuration of the E-E′ cross-section.

In the ninth step, as shown in FIGS. 32A to 32E, a polysilicon film 37 is formed so as to cover the semiconductor materials entirely. The polysilicon film 37 covers the LDD region 9 exposed to the outside. In a case where the semiconductor device 10 includes a logic section, steps of forming a circuit element in which to form the logic section (not illustrated) (for example, steps of: forming a well; forming a gate; and forming an extension) are carried out with the storage element area being protected. Thereafter, the oxide film and the polysilicon film are formed in the storage element area at the time of forming the circuit element.

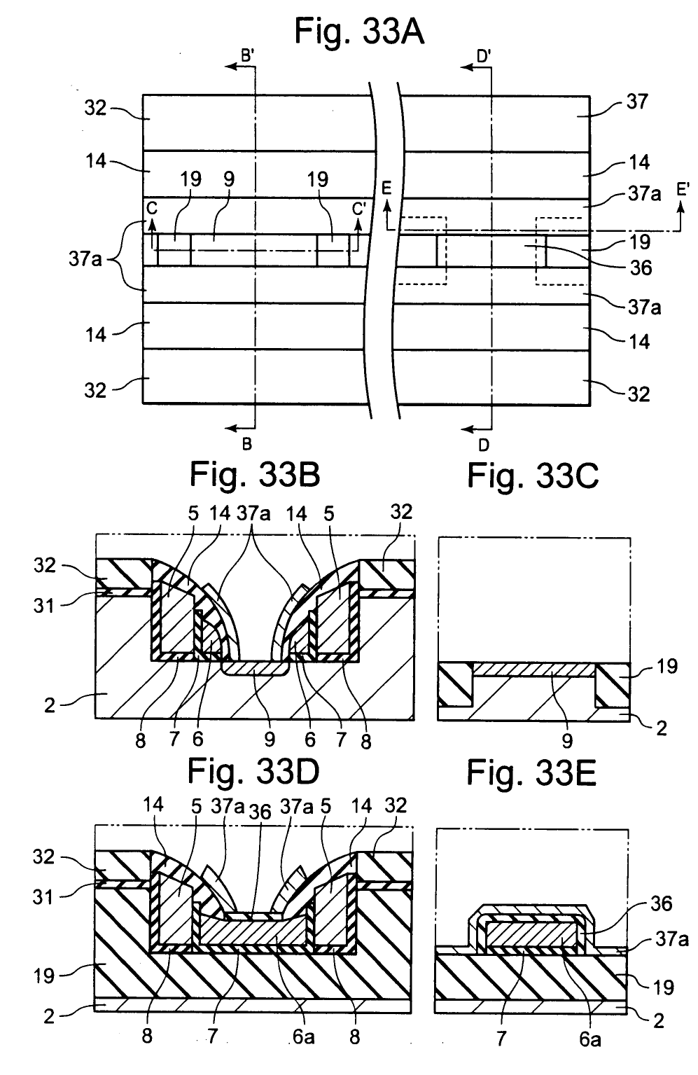

FIGS. 33A to 33E are diagrams illustrating a condition of a tenth step of manufacturing the semiconductor device of the second exemplary embodiment. FIG. 33A is a plan view of semiconductor materials used in the tenth step, which are viewed from above. FIG. 33B is a cross-sectional view illustrating a configuration of the B-B′ cross-section. FIG. 33C is a cross-sectional view illustrating a configuration of the C-C′ cross-section. FIG. 33D is a cross-sectional view illustrating a configuration of the D-D′ cross-section. FIG. 33E is a cross-sectional view illustrating a configuration of the E-E′ cross-section.

In the tenth step, portions of the polysilicon film 37 formed entirely on the semiconductor materials are etched back, and polysilicon sidewalls 37a are thus formed. In the B-B′ cross-section, as shown in FIG. 33B, each polysilicon sidewall 37a is formed in such a way as to cover the side and top surfaces of its corresponding memory gate 6. In addition, a surface of the LDD region 9 between the polysilicon sidewalls 37a is exposed to the outside. In the C-C′ cross-section, as shown in FIG. 33C, the LDD region 9 between the element isolation regions 19 is exposed to the outside. As shown in FIG. 33D, portions of the polysilicon film 37 formed entirely on the semiconductor materials are etched back, and polysilicon sidewalls 37a are thus formed. In the D-D′ cross-section, the polysilicon sidewalls 37a are configured in such a way as to face each other. Thus, a surface of the second protective oxide film 36 between the two polysilicon sidewalls 37a is exposed to the outside. In the E-E′ cross-section, as shown in FIG. 33E, the polysilicon sidewall 37a covers the second protective oxide film 36 on the memory gate contact region 6a.

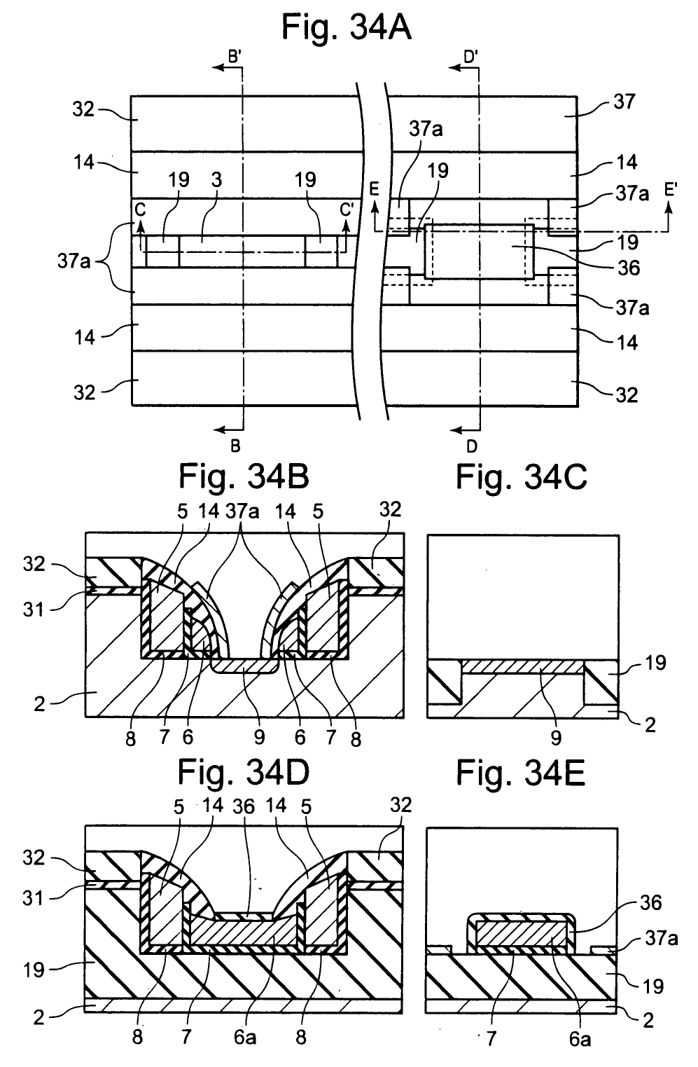

FIGS. 34A to 34E are diagrams illustrating a condition of an eleventh step of manufacturing the semiconductor device 10 of the second exemplary embodiment. FIG. 34A is a plan view of semiconductor materials used in the eleventh step, which are viewed from above. FIG. 34B is a cross-sectional view illustrating a configuration of the B-B′ cross-section. FIG. 34C is a cross-sectional view illustrating a configuration of the C-C′ cross-section. FIG. 34D is a cross-sectional view illustrating a configuration of the D-D′ cross-section. FIG. 34E is a cross-sectional view illustrating a configuration of the E-E′ cross-section.

In the eleventh step, portions of the polysilicon sidewalls 37a in the contact area are removed by use of a resist mask (not illustrated). As shown in FIGS. 34B and 34C, the polysilicon sidewalls 37a in the storage element area are kept in the same condition as those in the eighth step. In the contact area, as shown in FIG. 34D, in the D-D′ cross-section, the polysilicon sidewalls 37a are removed. In the E-E′ cross-section, as shown in FIG. 34E, the portion of the polysilicon sidewall 37a which has covered the second protective oxide film 36 is removed. At this time, the other portions of the polysilicon sidewall 37a which have been formed respectively at sides of the memory gate contact region 6a are protected by the resist mask. After the portions of the polysilicon sidewalls 37a are removed from the contact area, the resist mask is removed.

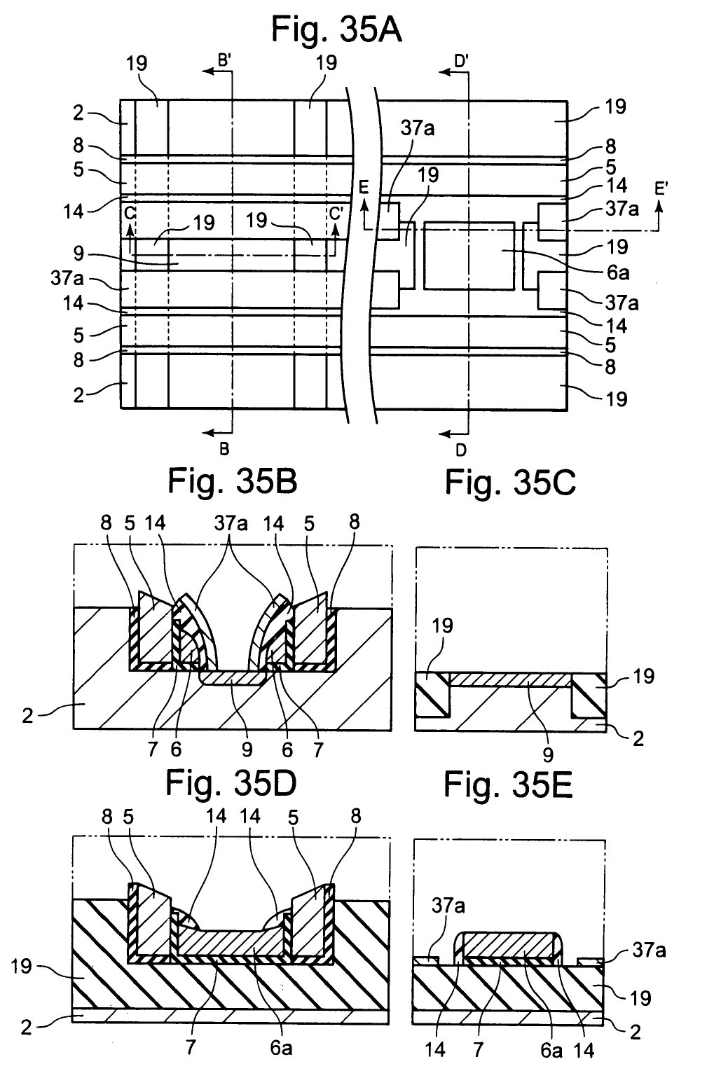

FIGS. 35A to 35E are diagrams illustrating a condition of a twelfth step of manufacturing the semiconductor device 10 of the second exemplary embodiment. FIG. 35A is a plan view of semiconductor materials used in the twelfth step, which are viewed from above. FIG. 35B is a cross-sectional view illustrating a configuration of the B-B′ cross-section. FIG. 35C is a cross-sectional view illustrating a configuration of the C-C′ cross-section. FIG. 35D is a cross-sectional view illustrating a configuration of the D-D′ cross-section. FIG. 35E is a cross-sectional view illustrating a configuration of the E-E′ cross-section.

In the twelfth step, the nitride films 32 are removed with the surface of the LDD region 9 and the surfaces of the respective polysilicon sidewalls 37a being protected by an oxide film (not illustrated). Thereafter, the oxide film and portions of the cell sidewalls 14 on the respective control gates 5 are removed. At this time, a portion of the element isolation region 19 between the adjacent LDD regions 9 may be lowered in some cases. In the case of the second exemplary embodiment, with reference to FIG. 35A, the LDD regions 9 in the adjacent storage elements 1 are connected together by the polysilicon sidewalls 37a. These polysilicon sidewalls 37a are turned into the first diffusion layer-side silicide 11 in the ensuing step. The first diffusion layer-side silicide 11 thus formed electrically connects the first source/drain diffusion layers 3 of the respective adjacent storage elements 1 together. For this reason, the storage elements 1 can be formed while not being affected by the height of each element isolation region 19.

In the twelfth step, as shown in FIG. 35B, in the B-B′ cross-section, the top surfaces of the control gates 5 and surfaces of the semiconductor substrate 2 at outer sides of the control gates 5 are exposed to the outside, respectively. In the C-C′ cross-section, as shown in FIG. 35C, the surface of the LDD region 9 having been temporarily covered with the oxide film (not illustrated) is exposed to the outside. In the D-D′ cross-section, as shown in FIG. 35D, the top surfaces of the control gates 5, a surface of the memory gate contact region 6a, and surfaces of the element isolation region 19 at outer sides of the control gates 5 are exposed to the outside, respectively. In the twelfth step, as shown in FIG. 35E, in the E-E′ cross-section, the cell sidewalls 14 each formed in a sidewall shape are formed on the side surfaces of the memory gate contact region 6a, respectively.

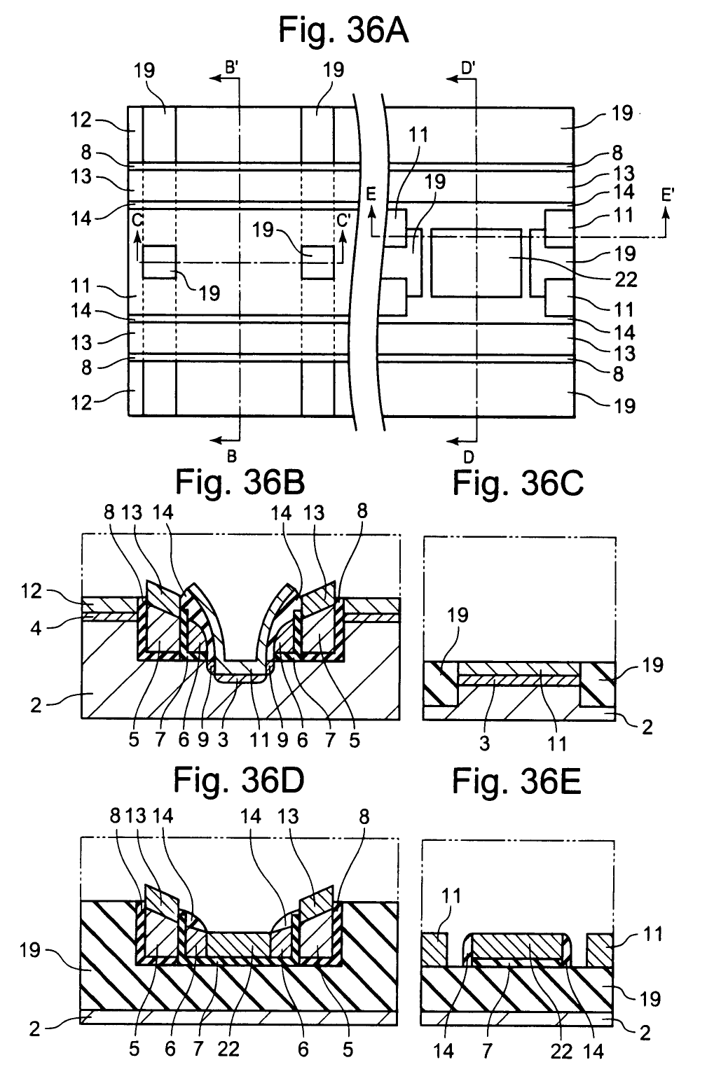

FIGS. 36A to 36E are diagrams illustrating a condition of a thirteenth step of manufacturing the semiconductor device 10 of the second exemplary embodiment. FIG. 36A is a plan view of semiconductor materials used in the thirteenth step, which are viewed from above. FIG. 36B is a cross-sectional view illustrating a configuration of the B-B′ cross-section. FIG. 36C is a cross-sectional view illustrating a configuration of the C-C′ cross-section. FIG. 36D is a cross-sectional view illustrating a configuration of the D-D′ cross-section. FIG. 36E is a cross-sectional view illustrating a configuration of the E-E′ cross-section.

In the thirteenth step, as shown in FIGS. 36B and 36C, to form the first source/drain diffusion layer 3 and the second source/drain diffusion layers 4, impurities (for example, As with a concentration of 2E15/cm²) are implanted, using the memory gates. 6 or the control gates 5 as masks. Subsequently, the polysilicon sidewalls 37a and a portion of the first source/drain diffusion layer 3 therebetween are silicided, and are thus made into the first diffusion layer-side silicide 11. At this time, together with this formation, the second diffusion layer-side silicides 12 and the control gate silicides 13 are formed. In the thirteenth step, as shown in FIGS. 36D and 36E, in the contact area, the memory gate silicide 22 is formed.

Thereafter, the sidewalls 15 are formed. Subsequently, the interlayer insulating film 18 (not illustrated) is configured. Afterward, the contact hole (not illustrated) in which to form the first source/drain contact 16 and the contact holes (not illustrated) in which to form the respective second source/drain contacts 17 are configured.

Although the invention has been described above in connection with several exemplary embodiments thereof, it will be appreciated by those skilled in the art that those exemplary embodiments is provided solely for illustrating the invention, and should not be relied upon to construe the appended claims in a limiting sense.

Further, it is noted that, notwithstanding any claim amendments made hereafter, applicant's intent is to encompass equivalents all claim elements, even if amended later during prosecution.

What is claimed is:

1. A non-volatile semiconductor memory device, comprising:
a semiconductor substrate;
a charge-storage layer that is formed above the semiconductor substrate;
a first gate that is formed above the charge-storage layer, and that includes a first surface and a second surface;
a second gate that is formed beside the first surface of the first gate;
an insulating layer that is formed above the second surface of the first gate;
a diffusion region that is formed on the semiconductor substrate at a position corresponding to the second surface of the first gate; and
a silicide layer that is formed above the insulating layer and the diffusion region.

2. The non-volatile semiconductor memory device according to claim 1,
wherein the silicide layer comprises:
a first part that is formed above the diffusion region; and
a second part that is formed above the insulating layer,
wherein the first part of the silicide layer is coupled to the diffusion region.

3. The non-volatile semiconductor memory device according to claim 2,
wherein the first part of the silicide layer is directly connected with the diffusion region.

4. The non-volatile semiconductor memory device according to claim 1,
wherein the insulating layer entirely covers the second surface of the first gate, and
wherein the silicide layer covers the insulating layer.

5. The non-volatile semiconductor memory device according to claim 1,
wherein the second surface comprises a sidewall shape, and
wherein the insulating layer is formed along the sidewall shape.

6. The non-volatile semiconductor memory device according to claim 5,
wherein the insulating layer covers the sidewall shape.

7 The non-volatile semiconductor memory device according to claim 2,
wherein the second part of the silicide layer entirely covers 4 a surface of the insulating layer.

8. The non-volatile semiconductor memory device according to claim 1, further comprising:
a contact that is formed above the silicide layer, and that is coupled to the silicide layer.

9. The non-volatile semiconductor memory device according to claim 1,
wherein the insulating layer comprises a first insulating layer, and
wherein the non-volatile semiconductor memory device further comprises:
a second insulating layer that is formed between the first gate and the second gate.

10. The non-volatile semiconductor memory device according to claim 9,
wherein the second insulating layer comprises a same material as that of the charge-storage layer.

11. The non-volatile semiconductor memory device according to claim 1,
wherein the diffusion region comprises a first diffusion region,
wherein the non-volatile semiconductor device further comprises:
a second diffusion region that is formed on the semiconductor substrate at a position corresponding to a surface of the second gate, and
wherein the first gate and the second gate are formed above a region between the first diffusion region and the second diffusion region.

12. The non-volatile semiconductor memory device according to claim 1,
wherein the diffusion layer comprises a first diffusion region,
wherein the semiconductor substrate comprises:
a trench that includes a bottom surface and a side surface,
wherein the charge-storage layer is formed above the bottom surface of the trench,
wherein the second gate is formed above the bottom surface of the trench and the side surface of the trench, and includes a third surface corresponding to the bottom surface of the trench and a fourth surface corresponding to the side surface of the trench,
wherein the first diffusion layer is formed on the bottom surface of the trench, and
wherein the non-volatile semiconductor memory device further comprises:
a second diffusion layer that is formed on the semiconductor substrate at a position corresponding to the fourth surface of the second gate outside of the trench.

13. The non-volatile semiconductor memory device according to claim 12,
wherein the semiconductor substrate comprises:
a first channel region that is located under the first gate;
a second channel region that is located under the third surface of the second gate; and
a third channel region that is located under the fourth surface of the second gate.

14. A nonvolatile semiconductor device, comprising,
a semiconductor substrate;
a first gate that is formed above the semiconductor substrate;
a second gate that is formed above the semiconductor substrate;
a diffusion region that is formed on the semiconductor substrate at a position corresponding to a region between the first gate and the second gate;
a first charge-storage layer that is formed above the semiconductor substrate at a position corresponding to a region between the first gate and the diffusion region;
a second charge-storage layer that is formed above the semiconductor substrate at a position corresponding to a region between the second gate and the diffusion region;
a third gate that is formed above the first charge-storage layer, and that includes a first surface corresponding to a side of the diffusion region;
a fourth gate that is formed above the second charge-storage layer, and that includes a second surface corresponding to the side of the diffusion region;
a first insulating layer that is formed above the first surface of the third gate;
a second insulating layer that is formed above the second surface of the fourth gate; and
a silicide layer that is formed above the diffusion region, the first insulating layer, and the second insulating layer.

15. The non-volatile semiconductor memory device according to claim 14,
wherein the first gate and the second gate are formed symmetrically with respect to the diffusion region,
wherein the first charge-storage layer and the second charge-storage layer are formed symmetrically with respect to the diffusion region, and
wherein the third gate and the fourth gate are formed symmetrically with respect to the diffusion region.

16. A manufacture method for a non-volatile semiconductor memory device, the manufacture method comprising:
forming a first gate above a semiconductor substrate;
forming a charge-storage layer at a side of the first gate;
forming a second gate above the charge-storage layer;
forming a diffusion region on the semiconductor substrate at a position corresponding to a side of the second gate;
covering the second gate with a sidewall insulating layer;
covering the sidewall insulating layer with a sidewall conductive layer; and
siliciding the sidewall conductive layer to form a silicide layer.

17. The manufacture method according to claim 16, wherein said first gate comprises a control gate and said second gate comprises a memory gate.

18 The manufacture method according to claim 16,
wherein the forming of the first gate comprises:
forming a sacrificial layer with an opening above the semiconductor substrate;
covering the sacrificial layer and the semiconductor substrate with a conductive layer for the first gate; and
etching the conductive layer to form the first gate at a side of the opening.

19. The manufacture method according to claim 16,
wherein the forming of the first gate comprises:
forming a trench in the semiconductor substrate;
covering the semiconductor substrate with a conductive layer for the first gate; and
etching the conductive layer to form the first gate at a side of the trench,
wherein the charge-storage layer, the second gate, and the diffusion region are formed within the trench.

20. The manufacture method according to claim 16,
wherein the forming of the second gate comprises:
covering the charge-storage layer and the semiconductor substrate with a conductive layer for the second gate; and
etching the conductive layer to form the second gate at the side of the first gate.

21. The manufacture method according to claim 16,
wherein the siliciding comprises:
siliciding a surface of the diffusion region.
